(19) United States
(12) Patent Application Publication
(10) Pub. No.: US 2013/0080096 A1
(43) Pub. Date: Mar. 28, 2013

(54) ARITHMETIC PROCESSING APPARATUS FOR CALCULATING INTERNAL RESISTANCE/OPEN-CIRCUIT VOLTAGE OF SECONDARY BATTERY

(71) Applicant: Yoshimasa Toki, Sagamihara-shi (JP)

(72) Inventor: Yoshimasa Toki, Sagamihara-shi (JP)

(21) Appl. No.: 13/702,804

(22) PCT Filed: Jun. 7, 2011
(86) PCT No.: PCT/JP2011/003208

§ 371 Date: Dec. 7, 2012

(30) Foreign Application Priority Data
Jun. 8, 2010 (JP) 2010-130886

(51) Int. Cl. G01R 31/36; G06F 15/00

(52) U.S. Cl. CPC G01R 31/3624; G06F 15/00
USPC 702/63

(57) ABSTRACT

In an arithmetic processing apparatus with a charge-discharge switching device for switching between a charge and a discharge of a secondary battery, a processor is provided for calculating an internal resistance or an open-circuit voltage of the secondary battery based on data including a voltage detected by a voltage sensor and a current detected by a current sensor. The processor is configured to derive an IV characteristic by using at least one of charging-period voltage and current data and discharging-period voltage and current data detected after a predetermined time has expired from a charge/discharge switching point, without using the voltage and current data of the secondary battery detected during a time duration from the charge/discharge switching point to the predetermined time, and configured to calculate the internal resistance or the open-circuit voltage from the derived IV characteristic.

### TECHNICAL FIELD

The present invention relates to an arithmetic processing apparatus for calculating an internal resistance and/or an open-circuit voltage of a secondary battery.

### BACKGROUND ART

Patent document 1 has disclosed an operation method for calculating, based on sampled data about a discharge current and a discharge voltage of a battery, an internal resistance and an open-circuit voltage of the battery from an IV characteristic, and for calculating a maximum discharge power of the battery based on the calculated internal resistance and the calculated open-circuit voltage.

### CITATION LIST

### Patent Literature

Patent document 1: Japanese Patent Provisional Publication No. 10-104325 (A)

### SUMMARY OF INVENTION

### Technical Problem

However, in the case of the previously-discussed prior-art operation method, the detected voltage and current values of the battery, used for arithmetic operation from the IV characteristic, tend to vary depending on a state of the battery when a vehicle is running. Thus, there is a possibility for errors for the calculated internal resistance to occur.

### Solution to Problem

It is, therefore, in view of the previously-described disadvantages of the prior art, an object of the invention to provide an arithmetic processing apparatus configured to suppress arithmetic errors for an internal resistance and/or an open-circuit voltage of a secondary battery.

In order to accomplish the aforementioned and other objects of the invention, an arithmetic processing apparatus is configured to calculate an internal resistance and/or an open-circuit voltage of a secondary battery from an IV characteristic, using at least one of charge voltage and current data and discharge voltage and current data, detected after a predetermined time has expired from a point of time when switching between charge and discharge occurs.

### Advantageous Effects of Invention

Therefore, according to the arithmetic processing apparatus of the present invention, an internal resistance and/or an open-circuit voltage of a secondary battery can be calculated based on detected data, which do not include unstable voltage and current data after switching between charge and discharge has occurred, thus effectively sup-pressing arithmetic errors for the internal resistance and/or the open-circuit voltage.

### BRIEF DESCRIPTION OF DRAWINGS

FIG. 1 is a block diagram illustrating an automotive vehicle employing an arithmetic processing apparatus of the first embodiment.

FIG. 2 is a block diagram illustrating the arithmetic processing apparatus of the first embodiment.

FIG. 3 is a graph illustrating a voltage-variation characteristic of a changing voltage with respect to discharge time in the battery of FIG. 2.

FIG. 4 is a graph illustrating a voltage-variation characteristic of a changing voltage with respect to charge time in the battery of FIG. 2.

FIG. 5 is a graph illustrating a characteristic of a voltage with respect to a current in the battery of FIG. 2.

FIG. 6 is a flowchart illustrating a control routine executed within the arithmetic processing apparatus of FIG. 2.

FIG. 7 is a graph illustrating a characteristic of an open-circuit voltage with respect to a state of charge (SOC) in the battery of FIG. 2.

FIG. 8 is a graph illustrating a characteristic of an internal resistance with respect to a state of charge (SOC) in the battery of FIG. 2.

FIG. 9 is a graph illustrating a characteristic of an internal-resistance conversion factor with respect to a state of charge (SOC) in the battery of FIG. 2.

FIG. 10 is a graph illustrating a characteristic of an internal-resistance conversion factor with respect to a battery temperature in the battery of FIG. 2.

FIG. 11 is a flowchart illustrating a control routine executed within the arithmetic processing apparatus of the second embodiment.

FIG. 12 is a block diagram illustrating the arithmetic processing apparatus of the third embodiment.

FIG. 13 is a flowchart illustrating a control routine executed within the arithmetic processing apparatus of the third embodiment.

FIG. 14 is a flowchart illustrating a control routine executed within the arithmetic processing apparatus of the fourth embodiment.

FIG. 15 is a flowchart illustrating a control routine executed within the arithmetic processing apparatus of the fifth embodiment.

### DESCRIPTION OF EMBODIMENTS

The arithmetic processing apparatus of the present invention is hereunder explained in detail in reference to the drawings of the embodiments shown.

### First Embodiment

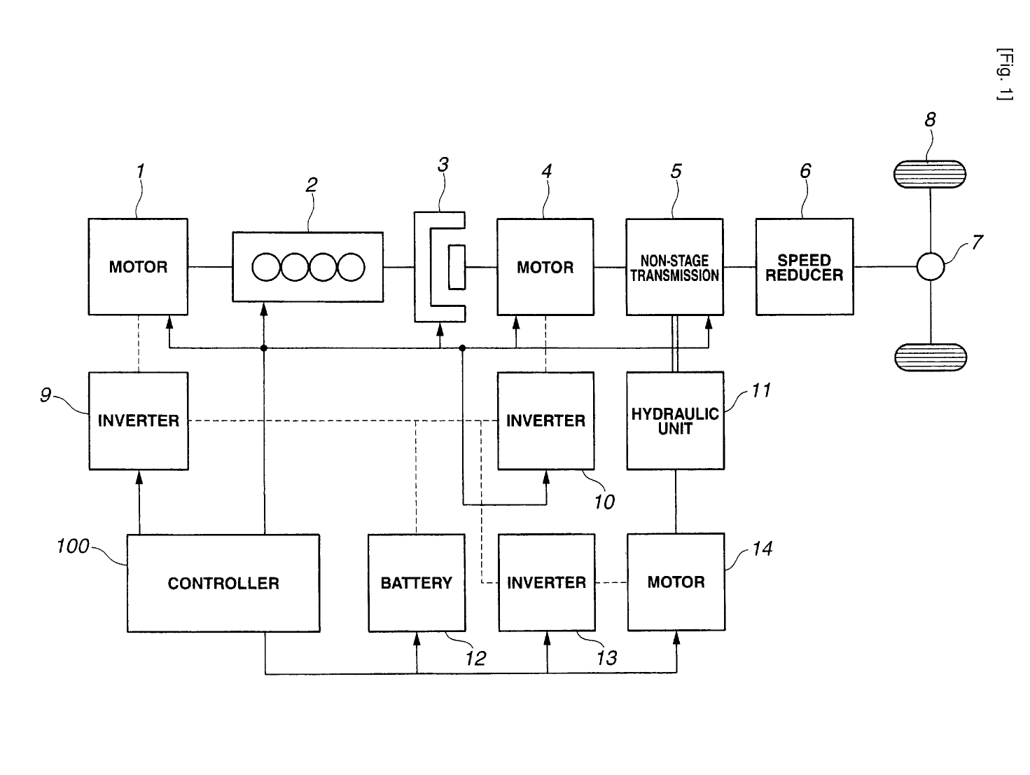

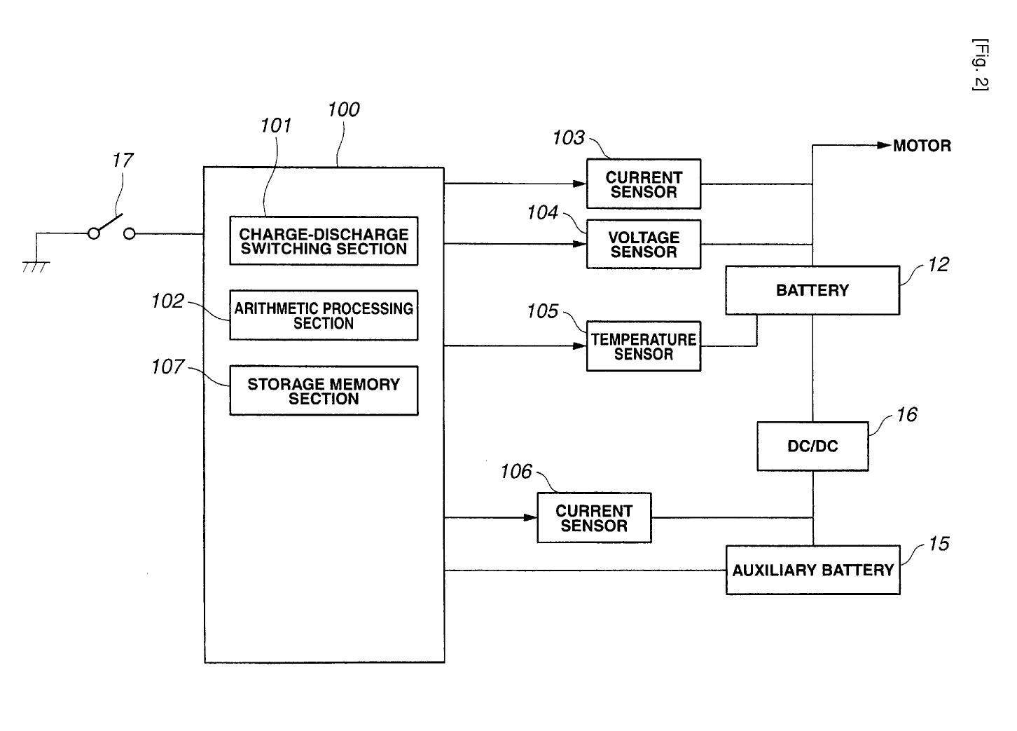

The arithmetic processing apparatus of the first embodiment is hereunder described in detail in reference to FIGS. 1-2. FIG. 1 shows the block diagram of the vehicle employing the arithmetic processing apparatus of the first embodiment. In FIG. 1, the solid line indicates a line of a mechanical-force transmission path, the arrow indicates a control line, the broken line indicates a power line, and the double line indicates a hydraulic system line. FIG. 2 shows the block diagram of the arithmetic processing apparatus of the first embodiment.

As shown in FIG. 1, the vehicle, which is equipped with the arithmetic processing apparatus of the first embodiment, employs a motor 1, an engine 2, a clutch 3, a motor 4, a non-stage transmission (CVT) 5, a speed reducer 6, a differential 7, and drive road wheels 8. Motor 1 is an alternating current motor, such as a three-phase synchronous motor, a three-phase induction motor or the like. Motor 1 is driven by an electric power supplied from a battery 12 via an inverter 9, to start up the engine 2. Motor 1 also functions as a generator, utilizing a power produced by the engine 2, so as to charge the battery 12. Engine 2 is a source of power that makes the vehicle move, and is an internal combustion engine that uses gasoline or light oil as fuel. Clutch 3 is a powder clutch, which is interleaved between the output shaft of engine 2 and the rotary shaft of motor 4, to enable or disable power transmission between engine 10 and motor 4. Torque transmitted through the clutch and exciting current applied to the clutch are almost in proportion to each other, and thus the magnitude of transmitted torque can be adjusted by the clutch 3.

Motor 4 is used for propelling and braking the vehicle. Motor 4 is an alternating current motor, such as a three-phase synchronous motor, a three-phase induction motor or the like. Motor 4 is driven by an electric power supplied from the battery 12 via an inverter 10. Non-stage transmission 5 is a continuously variable automatic transmission (CVT), whose transmission ratio is automatically continuously variable. The CVT is constructed by a belt-drive continuously variable transmission or a toroidal continuously variable transmission. For instance, in order to lubricate a clamp of the belt of the belt-drive CVT, pressurized working fluid is fed to the non-stage transmission 5 via a hydraulic unit 11. An oil pump (not shown) of hydraulic unit 11 is driven by a motor 14. Motor 14 is an alternating current motor, such as a three-phase synchronous motor, a three-phase induction motor or the like. Motor 14 is driven by an electric power supplied from the battery 12 via an inverter 13.

The output shaft of motor 1, the output shaft of engine 2, and the input shaft of clutch 3 are connected to each other. Also, the output shaft of clutch 3, the output shaft of motor 4, and the input shaft of non-stage transmission 5 are connected to each other. When clutch 3 has been engaged, engine 2 and motor 4 both serve as a propelling power source of the vehicle. When clutch 3 has been disengaged (released), motor 4 serves as a propelling power source of the vehicle. When clutch 3 has been engaged, motor 1 can be also used for propelling and braking the vehicle, and motor 4 can be also used for a startup of the engine 2 or power generation.

Inverters 9, 10, and 13 serve as dc-ac converters that convert a direct-current (dc) power supplied from the battery 12 into an alternating-current (ac) power and also supply the ac power to respective motors 1, 4, and 14. Inverters 9, 10, and 13 also serve as ac-dc converters that convert an ac power, generated by the motors 1, 4, and 14, into a dc power and also supply the dc power to battery 12 so as to charge the battery 12. Inverters 9, 10, and 13 are connected to each other via power lines serving as a dc link, and thus electric power, generated by a certain motor of motors 1, 4, and 14, which motor is in an energy-regeneration operating mode, can be supplied to a certain motor of motors 1, 4, and 14, which motor is in a power-running mode, without passing through the battery 12.

A secondary battery, such as a lithium-ion battery, a nickel-hydride battery, or a lead-acid storage battery is used as the battery 12.

A controller 100 incorporates therein a microcomputer, recording media, peripheral component parts, and various actuators. Controller 100 is configured to control a revolution speed and an output torque of engine 2 and a transmission ratio of non-stage transmission 5. Controller 100 is also configured to control motors 1, 4, and 14, and inverters 9, 10, and 13, and battery 12, so as to control a revolution speed and an output torque of each of motors 1, 4, and 14, an output power generated from battery 12, and a charge power charged in battery 12, and further configured to manage a charge and a discharge of battery 12.

Alternatively, assuming that direct-current motors are used as motors 1, 4, and 14, dc/dc converters may be used instead of inverters 9, 10, 13.

As shown in FIG. 2, an auxiliary battery 15, a DC/DC converter 16, the battery 12, and a vehicle key switch 17 are connected to controller 100. Auxiliary battery 15 is configured to supply an electric power to each of a control equipment containing the controller 100 and accessories (not shown) and the like. Auxiliary battery 15 is charged by an electric power delivered from battery 12 through DC/DC converter 16. Vehicle key switch 17 is a vehicle drive switch in which switching between turning-on and turning-off is made by the vehicle occupant.

An electric-current sensor 106 is connected to the power line between battery 12 and auxiliary battery 15, for detecting the magnitude of electric current flow through the power line between battery 12 and auxiliary battery 15. As compared to the magnitude of electric current flow from battery 12 to the motor, the magnitude of electric current flow through the power line between battery 12 and auxiliary battery 15 is low. Hence, the rated current of current sensor 106 is set to be lower than that of an electric-current sensor 103 (described later).

A voltage sensor 104 as well as current sensor 103 is connected to the battery 12. Current sensor 103 is provided for detecting the magnitude of electric current outputted from battery 12 to inverter 10 or to motor 4 via the inverter, and for detecting the magnitude of charge current charged in battery 12. Voltage sensor 104 is provided for detecting a value of voltage of battery 12. Current sensor 103 and voltage sensor 104 are configured to cyclically detect informational data about electric current and voltage of battery 12, every predetermined sampling time intervals. A temperature sensor 105 is provided for detecting a temperature of battery 12.

Controller 100 is configured to be connected to current sensor 103, voltage sensor 104, and temperature sensor 105 for detecting a discharge current, a charge current, a terminal voltage, and a temperature of battery 12, and for managing the battery 12 based on the obtained informational data including the detected current and voltage of the battery, and also configured to be connected to current sensor 106 for detecting a discharge current and a charge current of auxiliary battery 15 and for managing the auxiliary battery 15 based on the obtained informational data including the detected current and voltage of the auxiliary battery.

Controller 100 includes a charge-discharge switching section (a charge-discharge switching device) 101 and an arithmetic processing section (an arithmetic-logic processor) 102. Charge-discharge switching section 101 is a control part, which is provided for switching between a discharge from battery 12 to each of motors 1, 4, and 14 and a charge from each of motors 1, 4, and 14 to battery 12. For instance, in the presence of a driver's motor-output-torque requirement, battery 12 is discharged. Conversely in the case of energy regeneration control mode of the motor, battery 12 is charged. That is, switching between discharge and charge in battery 12 is executed depending on a running state of the vehicle. The charge/discharge switching action does not have a constant periodicity. Arithmetic processing section 102 is an arithmetic processing part, which is provided for calculating an internal resistance and an open-circuit voltage of battery 12.

Controller 10 also includes a storage memory section 107, which is constructed by recording media, such as storage memories.

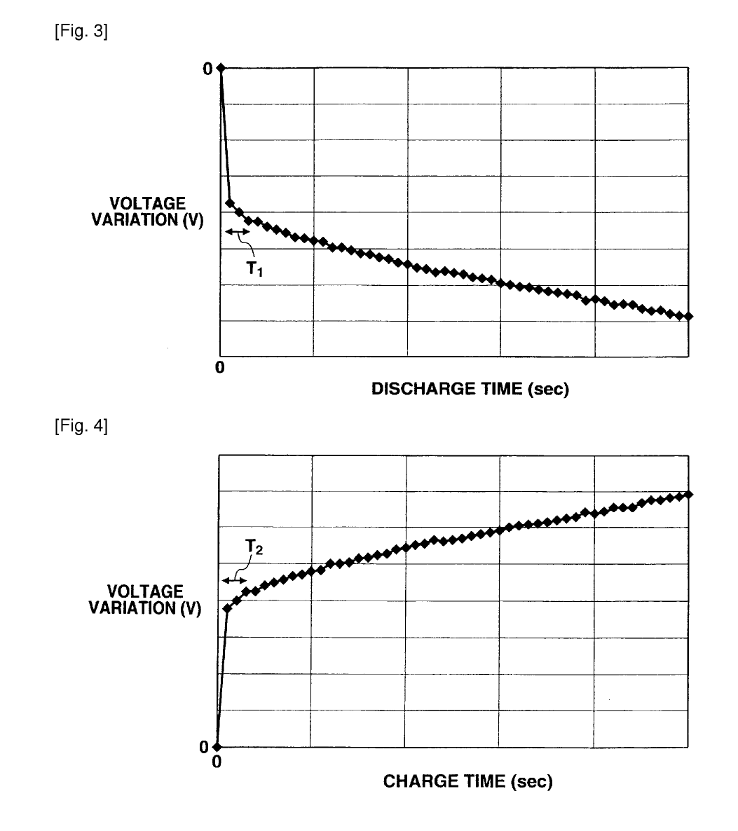

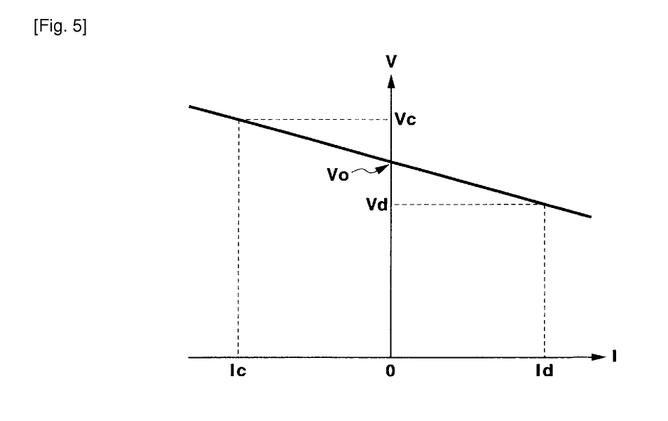

A method of calculating an internal resistance “R” and an open-circuit voltage “Vo” of battery 12 by means of the arithmetic processing apparatus of the first embodiment is hereunder described in reference to FIGS. 3-5. FIG. 3 is the graph illustrating the discharge-time versus voltage-variation characteristic of battery 12, FIG. 4 is the graph illustrating the charge-time versus voltage-variation characteristic of battery 12, and FIG. 5 is the graph illustrating the current versus voltage characteristic (IV characteristic) of battery 12.

First, by means of current sensor 103 and voltage sensor 104, controller 100 detects electric current and voltage of battery 12 every predetermined sampling time intervals, when the vehicle is running. Then, charge-discharge switching section 101 performs charge/discharge switching of battery 12 by controlling motor 4 and inverter 10, depending on the current running state of the vehicle. For instance, in the presence of a requirement of a load on motor 4 during a starting period of the vehicle, charge-discharge switching section 101 executes charge-to-discharge switching control of battery 12. Conversely during the energy-regeneration operating mode, charge-discharge switching section 101 executes discharge-to-charge switching control of battery 12. That is, charge-discharge switching section 101 is configured to switch between charge and discharge in battery 12, under a power-supply enabling state where an electric power supply from battery 12 to each of battery loads, such as motor 4 or the like, is enabled. Arithmetic processing section 102 is configured to calculate, based on the timing of charge/discharge switching, performed by charge-discharge switching section 101, and informational data detected every predetermined sampling time intervals, an internal resistance and an open-circuit voltage of battery 12.

In calculating internal resistance and open-circuit voltage of battery 12, when charge-to-discharge switching has been performed by charge-discharge switching section 101, arithmetic processing section 102 calculates the internal resistance and the open-circuit voltage, using detected data during the charging period and detected data during the discharging period. Hereupon, the discharging-period detected data mean voltage and current data detected after a first predetermined time has expired from a charge-to-discharge switching point, used as a reference.

Conversely when discharge-to-charge switching has been performed by charge-discharge switching section 101, arithmetic processing section 102 calculates the internal resistance and the open-circuit voltage, using detected data during the charging period and detected data during the discharging period. Hereupon, the charging-period detected data mean voltage and current data detected after a second predetermined time has expired from a discharge-to-charge switching point, used as a reference.

Arithmetic processing section 102 is configured to extract, based on the predetermined sampling time interval and the timing of charge/discharge switching performed by charge-discharge switching section 101, detected data, used as operation objects. That is, when charge/discharge switching has been performed by charge-discharge switching section 101 while detecting voltage and current of battery 12 every predetermined sampling time intervals by current sensor 103 and voltage sensor 104, arithmetic processing section 102 excludes discharge-period voltage and current data detected during a time duration from the charge-to-discharge switching point to the first predetermined time and excludes charge-period voltage and current data detected during a time duration from the discharge-to-charge switching point to the second pre-determined time, and also extracts discharge-period voltage and current data detected after the first predetermined time has expired from the charge-to-discharge switching point and extracts charge-period voltage and current data detected after the second pre-determined time has expired from the discharge-to-charge switching point.

By the way, as shown in FIGS. 3-4, during a charge/discharge switching time period, the terminal voltage of battery 12 tends to fluctuate. As shown in FIG. 3, during a time duration from the charge-to-discharge switching point to a time T₁, a great drop in terminal voltage with respect to discharge time tends to occur. After the time T₁ has expired, it is verified that a drop in voltage with respect to discharge time becomes stable. In a similar manner, as shown in FIG. 4, during a time duration from the discharge-to-charge switching point to a time T₂, a great rise in terminal voltage with respect to charge time tends to occur. After the time T₂ has expired, it is verified that a rise in voltage with respect to charge time becomes stable. As a matter of course, calculating internal resistance and open-circuit voltage based on voltage data detected during a time period in which the terminal voltage of battery 12 is greatly fluctuating, results in a deterioration in operation accuracy.

Therefore, in the first embodiment, arithmetic processing section 102 is configured to calculate an internal resistance and an open-circuit voltage of battery 12, by excluding voltage and current data detected during a time duration from a charge/discharge switching point to a predetermined time (i.e., the first predetermined time or the second predetermined time), and by data-extracting and using voltage and current data detected after the predetermined time has expired from the charge/discharge switching point. The predetermined time corresponds to the first predetermined time in the case that charge-to-discharge switching occurs. The predetermined time corresponds to the second predetermined time in the case that discharge-to-charge switching occurs. The first predetermined time is a time duration from a charge-to-discharge switching point when charge-to-discharge switching has been performed by charge-discharge switching section 101 to a point of time when a change in voltage of battery 12 with respect to discharge time becomes stable. The second predetermined time is a time duration from a discharge-to-charge switching point when discharge-to-charge switching has been performed by charge-discharge switching section 101 to a point of time when a change in voltage of battery 12 with respect to charge time becomes stable. The predetermined time (i.e., the first predetermined time or the second predetermined time) from the charge/discharge switching point to the point of time when voltage of battery 12 becomes stable, is dependent on characteristics of battery 12. As seen from the battery-voltage-variation characteristics of FIGS. 3-4, the predetermined time can be preset or preprogrammed by plotting variations in voltage of battery 12 with respect to discharge time or charge time.

Within arithmetic processing section 102, an open-circuit voltage and an internal resistance of battery 12 are calculated from detected voltage and detected current included in detected data, used as operation objects. For instance, open-circuit voltage and internal resistance of battery 12 can be calculated from an IV linear characteristic as described later. In the embodiment, the arithmetic processing section uses the IV linear characteristic. In lieu thereof, for the purpose of arithmetic processing, an approximate second-order curve may be used.

Also, in the embodiment, in order to enhance the operation accuracy, after having extracted specific data from detected data, which specific data satisfy a predetermined condition as operation-object data, the IV linear characteristic is derived. When characteristic data of voltage with respect to charge/discharge time are normal characteristic data, the characteristic data are within a predetermined voltage-value range. Suppose that arithmetic processing as described later is executed, using some data of detected data, which fall outside of the predetermined voltage-value range. In such a case, there is a possibility for arithmetic errors to occur. For the reasons discussed above, arithmetic processing section 102 is configured to set threshold values for detected voltage and current data, as the predetermined condition, and also to calculate the internal resistance and the open-circuit voltage, using the detected data, which data are within the predetermined condition.

The operation method (arithmetic processing method) for calculating internal resistance and open-circuit voltage when charge-to-discharge switching occurs is hereunder explained in detail.

[Math.1]
As shown in FIG. 5, when a discharge current Id (>0) flows, due to an internal resistance of battery 12, the terminal voltage of battery 12 drops to a voltage value Vd. In contrast, when a charge current Ic (<0) flows, due to the internal resistance of battery 12, the terminal voltage of battery 12 rises to a voltage value Vc. The internal resistance R, corresponding to a gradient of an IV linear characteristic, which IV characteristic is determined based on discharge current Id and terminal voltage Vd that are detected current and voltage data during the discharging period, and charge current Ic and terminal voltage Vc that are detected current and voltage data during the charging period, is derived from the following mathematical expression (1).

R=|(Vd−Vc)/(Id−Ic)| Math 1

On the other hand, the open-circuit voltage Vo, corresponding to an intercept of the IV linear characteristic is derived from the following mathematical expression (2) or the following mathematical expression (3).

Vo=Vd−(Vd−Vc)/(Id−Ic)Id Math 2

Vo=Vc−(Vd−Vc)/(Id−Ic)Ic Math 3

In this manner, the internal resistance R and the open-circuit voltage Vo of battery 12 are arithmetically calculated.

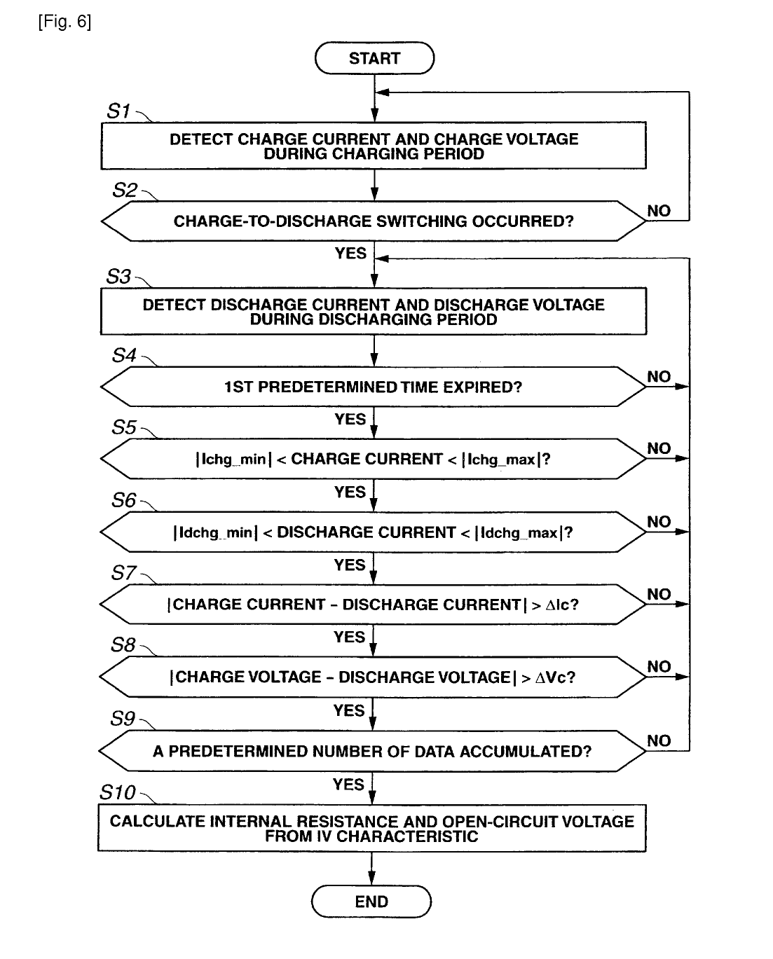

The operation procedure of internal resistance and open-circuit voltage of battery 12, executed within the arithmetic-processing apparatus of the first embodiment, is hereunder explained in reference to FIG. 6. FIG. 6 is the flowchart illustrating the operation procedure executed within the arithmetic processing apparatus of the first embodiment. FIG. 6 shows the operation procedure of internal resistance R and open-circuit voltage Vo when charge-to-discharge switching occurs.

At step S1, controller 100 detects, based on input information from current sensor 103 and voltage sensor 104, charge current and charge voltage of battery 12 during the charging period.

At step S2, controller 100 determines whether switching from charge to discharge has been performed by charge-discharge switching section 101. When charge-to-discharge switching has not occurred, the routine returns back to step S1, so as to detect again charge current and charge voltage. In contrast, when charge-to-discharge switching has occurred, the routine proceeds to step S3.

At step S3, controller 100 detects, based on input information from current sensor 103 and voltage sensor 104, discharge current and discharge voltage of battery 12 during the discharging period.

Next, at step S4, a check is made to determine whether the first predetermined time has expired from the charge-to-discharge switching point. When the first predetermined time has not expired, it is determined that the data, detected through step S3, are greatly fluctuating and unsuitable for operation objects. Thus, the routine returns to step S3, so as to detect again voltage and current of battery 12. In contrast, when the first predetermined time has expired, the routine proceeds to step S5.

Subsequently to the above, at step S5, a check is made to determine whether the charge current included in the detected data is higher than a charge-current lower limit (Ichg_min) and lower than a charge-current upper limit (Ichg_max). The charge-current lower limit (Ichg_min) and the charge-current upper limit (Ichg_max) represent preset threshold values for detected data used for deriving the IV characteristic. The detected current, lower than the charge-current lower limit (Ichg_min), or the detected current, higher than the charge-current upper limit (Ichg_max), does not appear on the IV characteristic, and thus these detected current data can be excluded from operation objects. The IV characteristic can be derived as a straight line, which varies depending on a state of battery 12, but a fluctuation range of the IV characteristic can be predetermined depending on characteristics of battery 12, the use environment usually assumed, and the state of battery 12. Hence, fully taking account of the predetermined fluctuation range, the charge-current lower limit (Ichg_min) and the charge-current upper limit (Ichg_max) are preset.

When the answer to step S5 is in the affirmative, that is, the detected charge current is higher than the charge-current lower limit (Ichg_min) and lower than the charge-current upper limit (Ichg_max), the routine proceeds to step S6. Conversely when the answer to step S5 is in the negative, that is, the detected charge current is lower than the charge-current lower limit (Ichg_min) or higher than the charge-current upper limit (Ichg_max), the first detected data including the above-mentioned charge current is excluded from operation object and then the routine returns to step S3.

In a similar manner, at step S6, a check is made to determine whether the discharge current included in the detected data is higher than a discharge-current lower limit (Idchg_min) and lower than a discharge-current upper limit (Idchg_max). In the same manner as the charge-current lower limit (Ichg_min) and the charge-current upper limit (Ichg_max), the discharge-current lower limit (Idchg_min) and the discharge-current upper limit (Idchg_max) represent preset threshold values for detected data used for deriving the IV characteristic. The detected current, lower than the discharge-current lower limit (Idchg_min), or the detected current, higher than the discharge-current upper limit (Idchg_max), does not appear on the IV characteristic, and thus these detected current data can be excluded from operation objects.

When the answer to step S6 is in the affirmative, that is, the detected discharge current is higher than the discharge-current lower limit (Idchg_min) and lower than the discharge-current upper limit (Idchg_max), the routine proceeds to step S7. Conversely when the answer to step S6 is in the negative, that is, the detected discharge current is lower than the discharge-current lower limit (Idchg_min) or higher than the discharge-current upper limit (Idchg_max), the second detected data including the above-mentioned discharge current is excluded from operation object and thus one execution cycle of the arithmetic operation terminates.

### [Math.2]

Subsequently to the above, at step S7, within the controller 100, a check is made to determine whether the electric-current difference between the detected charge current and the detected discharge current is greater than an electric-current finite-difference threshold value ΔIc (delta Ic). The electric-current finite-difference threshold value ΔIc is a threshold value needed to ensure the operation accuracy. That is, in the embodiment, for the purpose of enhancing the operation accuracy by the use of the detected current data having a great electric-current difference, when the electric-current difference between the detected charge current and the detected discharge current is less than the electric-current finite-difference threshold value ΔIc, these detected current data are excluded from operation objects and then the routine returns to step S3.

### [Math.3]

When the answer to step S7 is in the affirmative, that is, the electric-current difference between the detected charge current and the detected discharge current is greater than the electric-current finite-difference threshold value ΔIc, the routine proceeds to step S8. Conversely when the answer to step S7 is in the negative, that is, the electric-current difference between the detected charge current and the detected discharge current is less than the electric-current finite-difference threshold value ΔIc, these detected data including the charge current and the discharge current are excluded from operation objects.

In the case that a plurality of charge current data and a plurality of discharge current data are included in the detected data, a difference may be calculated each and every charge and discharge current data set. Alternatively, only the difference between the highest charge current of a plurality of charge current data and the highest discharge current of a plurality of discharge current data may be calculated.

### [Math.4]

Subsequently to the above, at step S8, within the controller 100, a check is made to determine whether the voltage difference between the detected charge voltage and the detected discharge voltage is greater than a voltage finite-difference threshold value ΔVc. The voltage finite-difference threshold value ΔVc is a threshold value needed to ensure the operation accuracy. That is, in the embodiment, for the purpose of enhancing the operation accuracy by the use of the detected voltage data having a great voltage difference, when the voltage difference between the detected charge voltage and the detected discharge voltage is less than the voltage finite-difference threshold value ΔVc, these detected voltage data are excluded from operation objects and then the routine returns to step S3.

### [Math.5]

When the answer to step S8 is in the affirmative, that is, the voltage difference between the detected charge voltage and the detected discharge voltage is greater than the voltage finite-difference threshold value ΔVc, the routine proceeds to step S9. Conversely when the answer to step S8 is in the negative, that is, the voltage difference between the detected charge voltage and the detected discharge voltage is less than the voltage finite-difference threshold value ΔVc, these detected data including the charge voltage and the discharge voltage are excluded from operation objects.

In the case that a plurality of charge voltage data and a plurality of discharge voltage data are included in the detected data, a difference may be calculated each and every charge and discharge voltage data set. Alternatively, only the difference between the highest charge voltage of a plurality of charge voltage data and the highest discharge voltage of a plurality of discharge voltage data may be calculated.

At step S9, controller 100 determines whether detected data, used as operation objects for calculating an internal resistance and an open-circuit voltage, have been ac-cumulated to a predetermined number. In the embodiment, information about discharge current and discharge voltage is detected every predetermined sampling time intervals. Thus, the predetermined number of data corresponds to the number of detections. The predetermined number is a preset value. The predetermined number is dependent on a required operation accuracy. When the answer to step S9 is in the affirmative, that is, the predetermined number of suitable data have been accumulated in controller 100, the routine proceeds to step S10. Conversely when the answer to step S9 is in the negative, that is, the predetermined number of suitable data have not yet been accumulated in controller 100, the routine returns to step S3.

At step S10, the IV characteristic is derived by the use of detected data satisfying the predetermined condition, as shown in steps S5-S8, and then an internal resistance and an open-circuit voltage of battery 12 are calculated from the derived IV characteristic.

As discussed above, the arithmetic processing apparatus of the first embodiment is configured to calculate an internal resistance and/or an open-circuit voltage of battery 12 from the IV characteristic derived, while using charge voltage and current data and/or discharge voltage and current data, detected after a predetermined time has expired from a charge/discharge switching point, without using any voltage and current data detected during a time duration from the charge/discharge switching point to the predetermined time. Hence, according to the first embodiment, voltage and current of battery 12 can be detected, while avoiding the time period that battery 12 is in an unstable state and thus battery voltage fluctuations are great, and thereafter internal resistance and/or open-circuit voltage can be calculated by the use of the detected data. As a result, the IV characteristic can be derived accurately, thus enhancing the operation accuracy of internal resistance and/or open-circuit voltage.

Under a situation where charge/discharge switching points of battery 12 are fluctuating depending on a running state of the vehicle, there is no regularity between a point of time of charge/discharge switching performed by charge-discharge switching section 101 and the predetermined sampling time interval. There is a possibility that detected data, sampled every predetermined sampling time intervals, include data greatly fluctuating immediately after switching between charge and discharge. In the case of the first embodiment, under a power-supply enabling state where an electric power supply from battery 12 to a battery load, such as an electric motor or the like, is enabled, an internal resistance and/or an open-circuit voltage of battery 12 is calculated, while using data, detected outside of a time duration from the charge/discharge switching point to the predetermined time, without using any data detected during the time duration from the charge/discharge switching point to the predetermined time. Therefore, it is possible to remove undesirable fluctuations (errors) in transiently-fluctuating voltage data, detected immediately after switching between charge and discharge, occurring at an arbitrary point of time, and also to calculate internal resistance and/or open-circuit voltage, based on stable detected data. Thus, it is possible to enhance the operation accuracy of internal resistance and/or open-circuit voltage.

According to the embodiment, an internal resistance and an open-circuit voltage of the battery are calculated, using both charging-period detected voltage and current data and discharging-period detected voltage and current data. By the use of both the charging-period detected voltage and current data and the discharging-period detected voltage and current data, the voltage difference between the detected voltage data and the electric-current difference between the detected current data tend to become great. As a result, it is possible to more accurately derive the IV characteristic, thus enhancing the operation accuracy of internal resistance and/or open-circuit voltage.

Furthermore, according to the embodiment, an internal resistance and an open-circuit voltage of the battery are calculated, using both data detected after the first predetermined time has expired from the charge-to-discharge switching point and data detected after the second predetermined time has expired from the discharge-to-charge switching point. Therefore, the detected data, used to derive the IV characteristic, never include unstable voltage and current data, transiently fluctuating during the time duration from the charge-to-discharge switching point to the first predetermined time and during the time duration from the discharge-to-charge switching point to the second predetermined time. Thus, it is possible to enhance the operation accuracy of internal resistance and/or open-circuit voltage, thus suppressing errors for the calculated internal resistance and/or open-circuit voltage.

Additionally, according to the embodiment, by comparing detected current included in detected data with the predetermined condition, concretely, the charge-current upper limit (Ichg_max), the charge-current lower limit (Ichg_min), the discharge-current upper limit (Idchg_max), and the discharge-current lower limit (Idchg_min), data, which do not appear on the IV characteristic, are excluded from operation objects, prior to arithmetic processing. As a result, data, used as operation objects, are suitable data to derive the IV characteristic, thus enhancing the operation accuracy of internal resistance and/or open-circuit voltage.

### [Math.6]

Moreover, according to the embodiment, by comparing the electric-current difference between detected charge current and detected discharge current both included in detected data with the predetermined condition, concretely, the electric-current finite-difference threshold value ΔIc, data, which do not appear on the IV characteristic, are excluded from operation objects, prior to arithmetic processing. In a similar manner, according to the embodiment, by comparing the voltage difference between detected charge voltage and detected discharge voltage both included in detected data with the predetermined condition, concretely, the voltage finite-difference threshold value ΔVc, data, which do not appear on the IV characteristic, are excluded from operation objects, prior to arithmetic processing. As a result, data, used as operation objects, are suitable data to derive the IV characteristic, thus enhancing the operation accuracy of internal resistance and/or open-circuit voltage.

As described previously, according to the embodiment, an internal resistance and an open-circuit voltage of the battery are calculated, using both charging-period detected data and discharging-period detected data. In lieu thereof, an internal resistance and an open-circuit voltage of the battery may be calculated, using either one of charging-period detected data and discharging-period detected data. Also, it is not always necessary to calculate both an internal resistance and an open-circuit voltage. Either one of an internal resistance and an open-circuit voltage may be calculated.

In the embodiment, the time length of the first predetermined time and the time length of the second predetermined time may be set to be identical to each other. By virtue of setting of the same time length of the second predetermined time as that of the first predetermined time, it is possible to enhance the operation accuracy of internal resistance and/or open-circuit voltage.

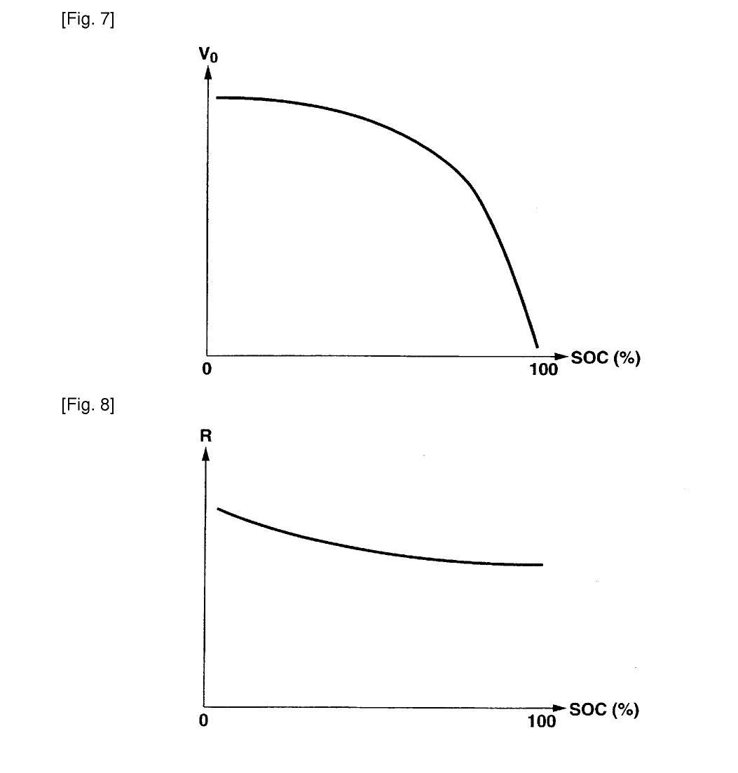

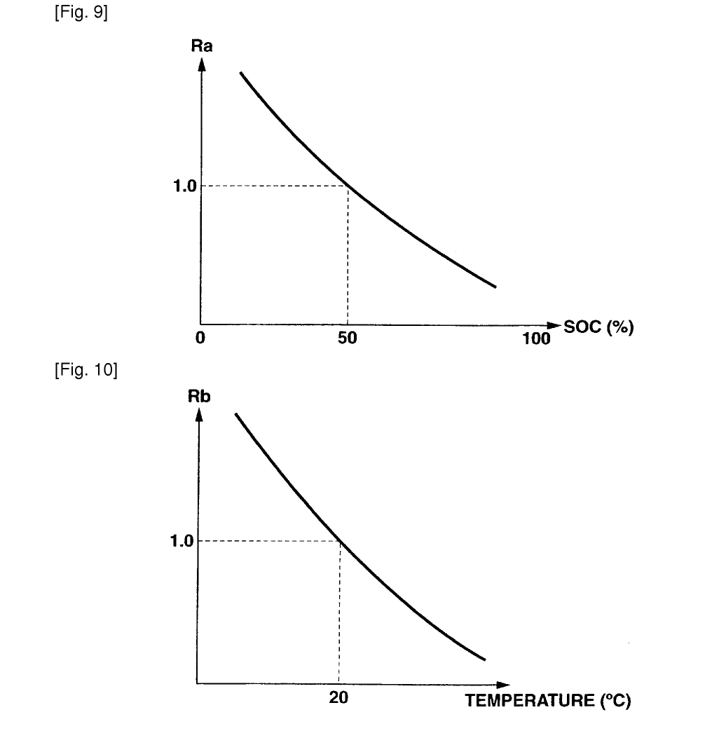

In the embodiment, the internal resistance, calculated through step S10, may be further corrected based on the open-circuit voltage, calculated according to the operation method as described previously, so as to more accurately calculate the internal resistance of battery 12. Generally, the internal resistance of battery 12 tends to vary depending on a state of charge, often abbreviated to “SOC” and given in percentage (%). Thus, the operation accuracy can be enhanced by reflecting the battery SOC in calculating the internal resistance. Details of the operation method of internal resistance of battery 12, taking account of the battery SOC, are hereunder described in reference to the characteristic curves of FIGS. 7-9. FIG. 7 is the graph illustrating the SOC versus open-circuit voltage Vo characteristic of battery 12, FIG. 8 is the graph illustrating the SOC versus internal-resistance R characteristic of battery 12, and FIG. 9 is the graph illustrating the SOC versus internal-resistance conversion factor Ra characteristic of battery 12.

The SOC (unit: %) of battery 12 is calculated based on the open-circuit voltage Vo, calculated by the operation method as described previously. As can be seen from the characteristic curve of FIG. 7, the SOC versus open-circuit-voltage Vo characteristic, showing the relationship (correlation) between the open-circuit battery voltage and the battery state of charge (SOC), is preset or predetermined depending on characteristics of the secondary battery. The preset lookup table, showing the relationship between the open-circuit voltage and the SOC of battery 12, is pre-stored in controller 100. The SOC of battery 12 can be calculated or retrieved based on the open-circuit voltage Vo, calculated through step S10 of FIG. 6, from the preset open-circuit-battery-voltage versus battery state of charge (SOC) lookup table.

As seen in FIG. 8, the internal resistance R tends to decrease, as the SOC of battery 12 increases. The battery SOC versus internal-resistance characteristic is determined depending on characteristics of the secondary battery used as battery 12. In the embodiment, as can be seen in FIG. 9, the battery SOC versus internal-resistance conversion factor Ra characteristic of battery 12 is preset, and the preset SOC-Ra characteristic is pre-stored in controller 100 in the form of the battery SOC versus internal-resistance conversion factor Ra lookup table. Regarding the battery SOC versus internal-resistance conversion factor Ra characteristic curve of FIG. 9, when the battery is half-charged and thus the battery SOC is 50%, the internal-resistance conversion factor Ra is set to “1.0”, serving as a reference point. The internal-resistance conversion factor Ra increases, as the SOC decreases. In other words, the internal-resistance conversion factor Ra decreases, as the SOC increases. Controller 100 retrieves and extracts, based on the SOC, which SOC is retrieved based on the open-circuit voltage Vo, calculated through step S10, from the lookup table of FIG. 7, the internal-resistance conversion factor Ra from the preset SOC versus Ra lookup table of FIG. 9. An SOC-corrected internal resistance of battery 12 is arithmetically calculated by multiplying the internal resistance R, calculated through step S10, with the conversion factor Ra. In this manner, the internal resistance, calculated through step S10, can be corrected so as to generate the SOC-corrected internal resistance of battery 12.

As discussed above, in the embodiment, the internal resistance, calculated from the IV characteristic, can be further corrected based on the state of charge (SOC) of battery 12, so as to generate the SOC-corrected internal resistance of battery 12, thereby enhancing the operation accuracy of the battery internal resistance.

Additionally, in the embodiment, the internal resistance, calculated through step S10, is further corrected based on the battery temperature detected by temperature sensor 105, so as to generate a temperature-corrected internal resistance of battery 12. Details of the operation method of internal resistance of battery 12, taking account of the battery temperature, detected by temperature sensor 105, are hereunder described in reference to FIG. 10. FIG. 10 is the graph illustrating the batter-temperature versus internal-resistance conversion factor Rb characteristic of battery 12.

Battery 12 has a characteristic that its internal resistance varies depending on a battery temperature. In the embodiment, arithmetic processing is performed, while using a battery temperature detected by temperature sensor 105. Generally, the internal resistance of battery 12 tends to become higher at low battery temperatures rather than high battery temperatures. The battery internal resistance has a characteristic that the internal resistance decreases in accordance with a rise in battery temperature. Thus, from the viewpoint of the battery temperature versus internal resistance characteristic, as can be seen in FIG. 10, the battery temperature versus internal-resistance conversion factor Rb characteristic of battery 12 is preset, and the preset battery-temperature versus conversion factor Rb characteristic is pre-stored in controller 100 in the form of the battery-temperature versus internal-resistance conversion factor Rb lookup table. Regarding the battery temperature versus internal-resistance conversion factor Rb characteristic curve of FIG. 10, when the battery temperature is 20° C., the internal-resistance conversion factor Rb is set to “1.0”, serving as a reference point. The internal-resistance conversion factor Rb increases, as the battery temperature falls. In other words, the internal-resistance conversion factor Rb decreases, as the battery temperature rises.

Controller 100 is further configured to read information about the battery temperature detected by temperature sensor 105, while calculating the battery internal resistance through step S10. Controller 100 retrieves and extracts, based on the detected battery temperature, the internal-resistance conversion factor Rb from the preset battery temperature versus internal-resistance conversion factor Rb lookup table of FIG. 10. A temperature-corrected internal resistance of battery 12 is arithmetically calculated by multiplying the internal resistance R, calculated through step S10, with the conversion factor Rb. In this manner, the internal resistance, calculated through step S10, can be corrected so as to generate the temperature-corrected internal resistance of battery 12.

As discussed above, in the embodiment, the internal resistance, calculated from the IV characteristic, can be further corrected based on the temperature of battery 12, so as to generate the temperature-corrected internal resistance of battery 12, thereby enhancing the operation accuracy of the battery internal resistance.

Furthermore, in the embodiment, the previously-described predetermined time and the previously-described threshold values shown in steps S5-S8, corresponding to the predetermined condition, may be varied and set depending on the temperature of battery 12, detected by temperature sensor 105. Generally, battery 12 has charge/discharge current variation characteristics, in which the charge/discharge current varies depending on a battery temperature. Also, battery 12 has charge/discharge time duration variation characteristics, in which the charge/discharge time duration varies when keeping the charge/discharge current constant. For instance, when the battery temperature rises, the discharge current becomes high, and thus the discharge time tends to lengthen, with the charge/discharge current kept constant. In the case of high battery temperatures, the detected voltage value and the detected current value, included in detected data, tend to become high. Also, in the case of high battery temperatures, the predetermined time from the charge/discharge switching point to the point of time when voltage and/or current of battery 12 becomes stable, tends to lengthen.

For the reasons discussed above, in the embodiment, when the detected temperature of battery 12 becomes high, the charge-current upper limit (Ichg_max), the charge-current lower limit (Ichg_min), the discharge-current upper limit (Idchg_max), and the discharge-current lower limit (Idchg_min) are set to high values. Conversely when the detected temperature of battery 12 becomes low, the charge-current upper limit (Ichg_max), the charge-current lower limit (Ichg_min), the discharge-current upper limit (Idchg_max), and the discharge-current lower limit (Idchg_min) are set to low values. Hence, even when the IV characteristic varies depending on a temperature change in battery 12, it is possible to set the predetermined condition for data-extraction of charge/discharge voltage and charge/discharge current within the predetermined range of data suitable for operation objects, responsively to the IV characteristic change. Thus, it is possible to enhance the operation accuracy.

Furthermore, in the embodiment, when the detected temperature of battery 12 becomes higher, the predetermined time from the charge/discharge switching point to the point of time when voltage and current of battery 12 becomes stable, tends to lengthen, and thus the predetermined time is corrected to a longer time length, as the battery temperature rises. Conversely when the detected temperature of battery 12 becomes lower, the predetermined time from the charge/discharge switching point to the point of time when voltage and current of battery 12 becomes stable, tends to shorten, and thus the predetermined time is corrected to a shorter time length, as the battery temperature falls. Hence, even when the predetermined time from the charge/discharge switching point to the point of time when voltage and current of battery 12 becomes stable, varies depending on a temperature change in battery 12, it is possible to set the predetermined condition for data-extraction of charge/discharge voltage and charge/discharge current within the predetermined range of data suitable for operation objects, responsively to the predetermined time change. Thus, it is possible to enhance the operation accuracy.

Moreover, in the embodiment, the previously-described predetermined time or the previously-described threshold values shown in steps S5-S8, corresponding to the pre-determined condition, may be varied and set depending on the deterioration rate of battery 12. Generally, battery 12 has charge/discharge current variation characteristics, in which the charge/discharge current varies depending on a battery deterioration rate. Also, battery 12 has charge/discharge time duration variation characteristics, in which the charge/discharge time duration varies when keeping the charge/discharge current constant. For instance, when the battery deterioration rate is low, the discharge current becomes high, and thus the discharge time tends to lengthen, with the charge/discharge current kept constant. In the case of low battery deterioration rates, the detected voltage value and the detected current value, included in detected data, tend to become high. Also, in the case of low battery deterioration rates, the predetermined time from the charge/discharge switching point to the point of time when voltage and current of battery 12 becomes stable, tends to lengthen.

For the purpose of calculating the deterioration rate of battery 12, a part of the processor of controller 100 may include a battery-deterioration-rate calculation section (a battery-deterioration-rate operation part). For instance, the battery-deterioration-rate calculation section is configured to compute latest up-to-date information about a battery capacity of battery 12 kept in its fully-charged condition and also compared it with an initial battery capacity of the same battery kept in the fully-charged condition for calculating a ratio between the latest up-to-date battery capacity and the initial battery capacity, and for deriving a battery deterioration rate. For instance, the battery capacity of the secondary battery kept in the fully-charged condition can be calculated based on the integrated value of discharge current, detected by current sensor 103.

For the reasons discussed above, in the embodiment, when the deterioration rate of battery 12 is low, the charge-current upper limit (Ichg_max), the charge-current lower limit (Ichg_min), the discharge-current upper limit (Idchg_max), and the discharge-current lower limit (Idchg_min) are set to high values. Conversely when the deterioration rate of battery 12 is high, the charge-current upper limit (Ichg_max), the charge-current lower limit (Ichg_min), the discharge-current upper limit (Idchg_max), and the discharge-current lower limit (Idchg_min) are set to low values. Hence, even when the IV characteristic varies depending on a deterioration rate of battery 12, it is possible to set the predetermined condition for data-extraction of charge/discharge voltage and charge/discharge current within the predetermined range of data suitable for operation objects, responsively to the IV characteristic change. Thus, it is possible to enhance the operation accuracy.

In the embodiment, in the case of high deterioration rates of battery 12, the predetermined time from the charge/discharge switching point to the point of time when voltage and current of battery 12 becomes stable, tends to shorten, and thus the predetermined time is corrected to a shorter time length. Conversely in the case of low deterioration rates of battery 12, the predetermined time from the charge/discharge switching point to the point of time when voltage and current of battery 12 becomes stable, tends to lengthen, and thus the predetermined time is corrected to a longer time length. Hence, even when the predetermined time from the charge/discharge switching point to the point of time when voltage and current of battery 12 becomes stable, varies depending on a deterioration rate of battery 12, it is possible to accurately set the timing for data-extraction of charge/discharge voltage and current data suitable for operation objects, responsively to the predetermined time change. Thus, it is possible to enhance the operation accuracy.

The level of the battery temperature and the deterioration rate of battery 12 can be determined or evaluated by comparing their preset threshold values (their reference values). On the basis of the comparison results, the predetermined time and the preset threshold values, corresponding to the predetermined condition, can be appropriately varied. Alternatively, the deterioration rate of battery 12 may be estimated or calculated by a generally-known method.

In the embodiment, internal resistance and open-circuit voltage of battery 12 are calculated under a situation where the battery state of charge (SOC) and the vehicle running state are varying every predetermined sampling time intervals for arithmetic operations. Thus, by converting the internal resistance and the open-circuit voltage, calculated through step S10, to respective standard conditions (e.g., the standard battery temperature of battery 12, such as 20° C., and the standard battery state of charge (SOC) of battery 12, such as 50%), the calculated internal resistance and the calculated open-circuit voltage may be normalized. There is a preset one-to-one correspondence between the calculated internal resistances and the battery temperatures of battery 12. There is a preset one-to-one correspondence between the calculated internal resistances and the battery SOCs of battery 12. In a similar manner, there is a preset one-to-one correspondence between the calculated open-circuit voltages and the battery temperatures of battery 12. Also, there is a preset one-to-one correspondence between the calculated open-circuit voltages and the battery SOCs of battery 12. These one-to-one correspondences (correlations) are stored in the storage memory section 107 of controller 100 in the form of the lookup tables. Controller 100 is further configured to convert the calculated internal resistance and the calculated open-circuit voltage to respective standard scales, taking account of the standard condition (e.g., the standard battery temperature and the standard battery state of charge (SOC)), from the respective pre-stored lookup tables. By virtue of such normalization, in the embodiment, even when data are detected and extracted under a condition of battery 12 except the standard condition, it is possible to calculate the normalized internal resistance and the normalized open-circuit voltage.

In the shown embodiment, for data-extraction, through steps S5 to S8, charge/discharge current, detected by current sensor 103, and charge/discharge voltage, detected by voltage sensor 104, are compared with respective threshold values. All arithmetic operations of steps S5 to S8 do not always have to be executed. Either one of the arithmetic operations of steps S5 to S8 may be executed. Furthermore, regarding steps S5 and S6, the detected current/voltage data may be compared to either the upper limit or the lower limit.

Battery 12 may be constructed by a battery pack having a plurality of battery cells. For instance, voltage may be detected each and every battery cell of the battery pack, and then an internal resistance and an open-circuit voltage of each of battery cells may be calculated in the same manner as described previously. In such a case, these calculation results can be significantly used for batter-cell capacity adjustment among the battery cells, thereby ensuring high-precision battery-cell-capacity adjustment and protection of battery 12.

Additionally, by detecting voltage each and every battery cell, and by calculating an internal resistance and an open-circuit voltage each and every battery cell, and by calculating the integrated value of the calculated internal resistances and the calculated open-circuit voltages of the battery cells, it is possible to calculate an internal resistance and an open-circuit voltage of the battery pack. However, from the viewpoint of the increased load on arithmetic calculations, in calculating an internal resistance and an open-circuit voltage of the battery pack, it is preferable to use a terminal voltage between the positive and negative terminals of the battery pack.

In the shown embodiment, arithmetic processing for internal resistance and open-circuit voltage is triggered at the timing of charge/discharge switching. In lieu thereof, such arithmetic processing may be triggered at a charge-to-discharge switching point or at a discharge-to-charge switching point.

In the shown embodiment, at step S4, the charge/discharge time duration (concretely, the discharge time), elapsed from the charge/discharge switching point (concretely, the charge-to-discharge switching point), is compared with the predetermined time (concretely, the first predetermined time). In lieu thereof, a detected voltage variation from the charge/discharge switching point may be compared with a given voltage-variation threshold value, for the reasons discussed below. That is, as shown in FIGS. 3-4, during the time duration from the charge-to-discharge switching point to the time T₁, and during the time duration from the discharge-to-charge switching point to the time T₂, voltage of battery 12 is unstable, and thus a variation in voltage with respect to charge/discharge time is great. In contrast, after the time T₁ has expired from the charge-to-discharge switching point, and after the time T₂ has expired from the discharge-to-charge switching point, voltage of battery 12 becomes stable, and thus a variation in voltage with respect to charge/discharge time becomes small. The battery-voltage-variation characteristics of FIGS. 3-4 are determined depending on characteristics of the secondary battery used as battery 12. For this reason, in this modification, a voltage-variation threshold value is preset, and a variation of voltage detected is compared to the voltage-variation threshold value. When the detected voltage variation is greater than the voltage-variation threshold value, it is determined that voltage of battery 12 is unstable and thus the detected voltage data is unsuitable for operation object. Conversely when the detected voltage variation is less than the voltage-variation threshold value, it is determined that voltage of battery 12 is stable and thus the detected voltage data is suitable for operation object. That is, in the modification, at step S4, controller 100 calculates a voltage variation with respect to unit time, based on a variation of the voltage detected at step S3 from the previous voltage detected one sampling cycle before. Then, controller 100 compares the calculated voltage variation with the preset voltage-variation threshold value. When the calculated voltage variation is greater than the voltage-variation threshold value, it is determined that the data, detected through step S3, are greatly fluctuating and unsuitable for operation objects. Thus, the routine returns to step S3, so as to detect again voltage and current of battery 12. In contrast, when the calculated voltage variation is less than the voltage-variation threshold value, the routine proceeds to step S5.

As discussed above, the arithmetic processing apparatus of the modification is configured to calculate an internal resistance and/or an open-circuit voltage of battery 12 from the IV characteristic derived, while using charge voltage data and/or discharge voltage data, including stable voltage data that the voltage variation with respect to unit time becomes less than the voltage-variation threshold value. Hence, according to the modification, internal resistance and/or open-circuit voltage can be calculated by the use of the detected data including stable voltage data, while avoiding the use of detected voltage data that battery 12 is in an unstable state and thus battery voltage fluctuations are great. As a result, the IV characteristic can be derived accurately, thus enhancing the operation accuracy of internal resistance and/or open-circuit voltage.

By the way, the control routine and control contents shown in FIG. 6 are exemplified in the presence of charge-to-discharge switching. As a matter of course, the inventive concept can be applied to the presence of discharge-to-charge switching, but, in such a case, detection of charging-period current/voltage executed at step S1 is replaced with detection of discharging-period current/voltage, checking for charge-to-discharge switching executed at step S2 is replaced with checking for discharge-to-charge switching, detection of discharging-period current/voltage executed at step S3 is replaced with detection of charging-period current/voltage, and the first predetermined time recited in step S4 is replaced with the second predetermined time.

In the shown embodiment, arithmetic processing section 102 is configured to exclude voltage and current data detected during a time duration from a charge/discharge switching point to a predetermined time (i.e., the first predetermined time or the second predetermined time), thereby inhibiting the voltage and current data, detected during the time duration from the charge/discharge switching point to the predetermined time, from being used. In lieu thereof, controller 100 may be configured so as not to detect voltage and current data during a time duration from a charge/discharge switching point to a predetermined time (i.e., the first predetermined time or the second predetermined time). That is, when charge/discharge switching has been performed by charge-discharge switching section 101, controller 100 does not detect voltage and current of battery 12 by controlling current sensor 103 and voltage sensor 104, during the time duration from the charge/discharge switching point to the predetermined time (i.e., the first predetermined time or the second predetermined time). By this, in calculating internal resistance and/or open-circuit voltage of battery 12 by arithmetic processing section 102, it is possible to calculate the internal resistance and the open-circuit voltage without using voltage and current data of battery 12 during the time duration from the charge/discharge switching point to the predetermined time (i.e., the first predetermined time or the second predetermined time).

In the shown embodiment, charge-discharge switching section 101 serves as charge-discharge switching means, current sensor 103 serves as current detection means, voltage sensor 104 serves as voltage detection means, temperature sensor 105 serves as temperature detection means, arithmetic processing section 102 serves as arithmetic processing means, storage memory section 107 serves as storage memory means, and the battery-deterioration-rate calculation section, constructing a part of the processor of controller 100, serves as battery-deterioration-rate calculation means.

### Second Embodiment

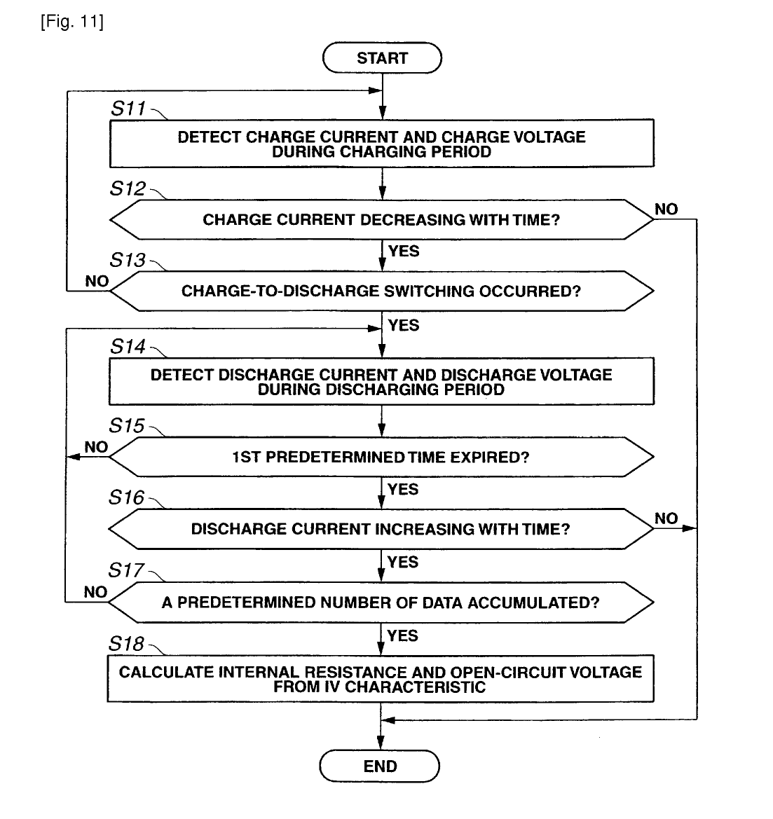

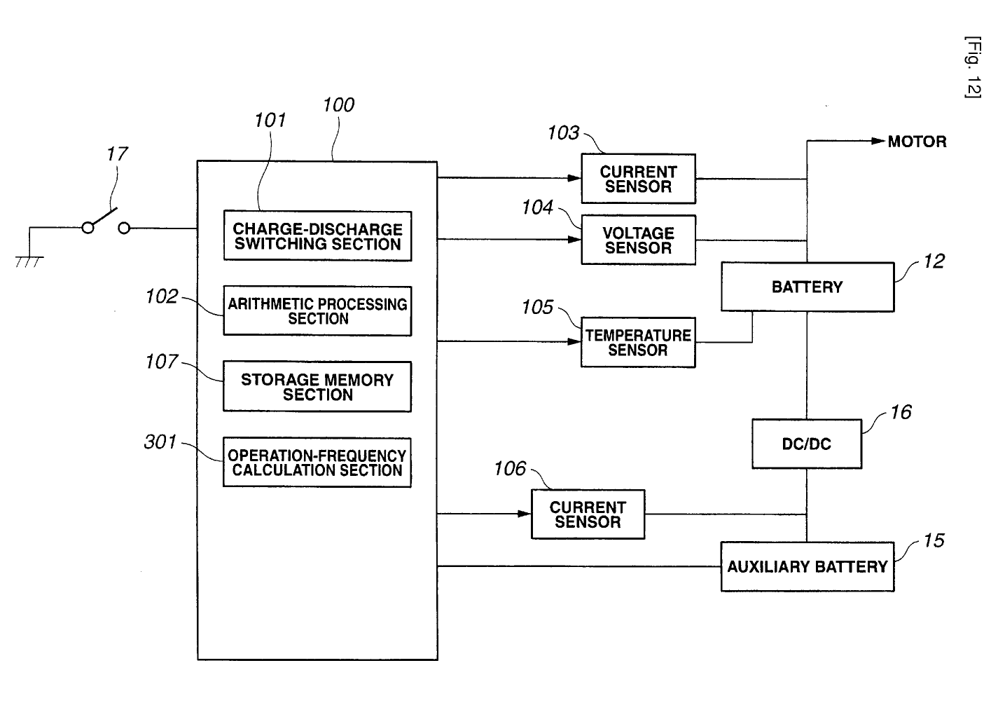

The arithmetic processing apparatus of the second embodiment is similar to that of the first embodiment except that the control contents of the second embodiment partly differ from the first embodiment. Thus, almost all of elements in the first embodiment (almost all effects provided by the first embodiment) will be applied to the corresponding elements of the second embodiment. FIG. 11 is the flowchart illustrating the operation procedure (the control routine) executed within the arithmetic processing apparatus of the second embodiment.

In the second embodiment, regarding data, detected by current sensor 103 and voltage sensor 104, the arithmetic processing apparatus is configured to calculate internal resistance and open-circuit voltage of battery 12, while taking full account of a change in detected current with time. The control routine and control contents of the second embodiment are hereunder described in detail in reference to the flowchart of FIG. 11.

At step S11, controller 100 detects, based on input information from current sensor 103 and voltage sensor 104, charge current and charge voltage of battery 12 during the charging period at predetermined sampling time intervals.

Next, at step S12, controller 100 determines, based on a result of comparison of the previous charge-current data detected one sampling cycle before with the current charge-current data detected at step S11, whether the charge current is decreasing with time. When the answer to step S12 is in the negative, that is, a decrease in charge current with time does not occur, one execution cycle of the arithmetic operation terminates. Conversely when the answer to step S12 is in the affirmative, that is, a decrease in charge current with time occurs, the routine proceeds to step S13. By the way, regarding step S12, in the case that the previous data detected one sampling cycle before does not correspond to the data detected during the charging period, it is determined that the charge current is decreasing with time and then the routine proceeds to step S13.

At step S13, controller 100 determines whether switching from charge to discharge has been performed by charge-discharge switching section 101. When charge-to-discharge switching has not occurred, the routine returns back to step S11, so as to detect again charge current and charge voltage. In contrast, when charge-to-discharge switching has occurred, the routine proceeds to step S14.

At step S14, controller 100 detects, based on input information from current sensor 103 and voltage sensor 104, discharge current and discharge voltage of battery 12 during the discharging period at predetermined sampling time intervals.

At step S15, a check is made to determine whether the first predetermined time has expired from the charge-to-discharge switching point. When the first predetermined time has not expired, it is determined that the data, detected through step S14, are greatly fluctuating and unsuitable for operation objects. Thus, the routine returns to step S14, so as to detect again voltage and current of battery 12. In contrast, when the first predetermined time has expired, the routine proceeds to step S16.

At step S16, controller 100 determines, based on a result of comparison of the previous discharge-current data detected one sampling cycle before with the current discharge-current data detected at step S14, whether the discharge current is increasing with time. When the answer to step S16 is in the negative, that is, an increase in discharge current with time does not occur, one execution cycle of the arithmetic operation terminates. Conversely when the answer to step S16 is in the affirmative, that is, an increase in discharge current with time occurs, the routine proceeds to step S17. By the way, regarding step S16, in the case that the previous data detected one sampling cycle before does not correspond to the data detected during the discharging period, it is determined that the discharge current is increasing with time and then the routine proceeds to step S17.

At step S17, controller 100 determines whether detected data, used as operation objects for calculating an internal resistance and an open-circuit voltage, have been ac-cumulated to a predetermined number. When the answer to step S17 is in the affirmative, that is, the predetermined number of suitable data have been accumulated in controller 100, the routine proceeds to step S18. Conversely when the answer to step S17 is in the negative, that is, the predetermined number of suitable data have not yet been accumulated in controller 100, the routine returns to step S14.

At step S18, the IV characteristic is derived based on the detected voltage and the detected current included in the detected data, and then an internal resistance and an open-circuit voltage of battery 12 are calculated from the derived IV characteristic.

As discussed above, the arithmetic processing apparatus of the second embodiment is configured to extract the detected data including charge current decreasing with detection time and the detected data including discharge current increasing with detection time as data suitable for operation objects, and also to calculate an internal resistance and an open-circuit voltage of the secondary battery by the use of the extracted data. By this, it is possible to enhance the operation accuracy of internal resistance and/or open-circuit voltage. Regarding data detected immediately after switching between charge and discharge, voltage and current of battery 12 tend to unstably fluctuate. When arithmetic processing is made with such unstable detected data, there is an increased tendency for the operation accuracy to be lowered. For the reasons discussed above, in the second embodiment, taking full account of a specified condition, that is, a decrease in charge current with detection time and/or an increase in discharge current with detection time, data suitable for operation objects can be extracted. Thus, it is possible to calculate an internal resistance and/or an open-circuit voltage, while excluding unsuitable data in deriving the IV characteristic. As a result of this, it is possible to enhance the operation accuracy.

### Third Embodiment

The arithmetic processing apparatus of the third embodiment is similar to that of the first embodiment except that, in the third embodiment, an operation-frequency calculation section (an operation-frequency counter) 301 is further provided in controller 100. Thus, almost all of elements in the first embodiment (almost all effects provided by the first embodiment) will be applied to the corresponding elements of the third embodiment. FIG. 12 is the block diagram illustrating the arithmetic processing apparatus of the third embodiment.

As shown in FIG. 12, in the arithmetic processing apparatus of the third embodiment, operation-frequency calculation section 301 is further provided in controller 100. Operation-frequency calculation section 301 is configured to calculate or measure the number of operations (calculations) completed in a unit time.

By the way, detected voltage and detected current of battery 12 vary depending on the deterioration rate of battery 12, the battery temperature, and the like. Therefore, the quantity of detected data, which satisfies the predetermined condition for data-detection (data-extraction) shown in steps S5 to S8 in FIG. 6, varies depending on the deterioration rate of battery 12, the battery temperature, and the like. For instance, when the battery temperature of battery 12 is high or when the deterioration rate of battery 12 is low, a value of electric current, which can be supplied from the battery, tends to become higher, and thus a dischargeable time tends to lengthen by keeping the discharge current value constant. Therefore, in extracting detected data suitable for operation objects, a charge/discharge current value becomes higher, or a data-detection time elapsed from the charge/discharge switching point becomes lengthened.

Owing to the lengthened detection time, the quantity of data, which satisfies the pre-determined data-detection condition, tends to increase, unless the predetermined data-detection condition is changed. As a result, the operation frequency tends to become high. Therefore, in the third embodiment, when the operation frequency per unit time, calculated by operation-frequency calculation section 301, becomes high, a range of the predetermined data-detection condition is narrowed such that a data-extraction condition for data used as operation objects becomes more severe. As a result, it is possible to enhance the operation accuracy, while suppressing the operation frequency.

Conversely when the battery temperature of battery 12 is low or when the deterioration rate of battery 12 is high, a value of electric current, which can be supplied from the battery, tends to become lower, and thus a dischargeable time tends to shorten by keeping the discharge current value constant. Therefore, in extracting detected data suitable for operation objects, a charge/discharge current value becomes lower, or a data-detection time elapsed from the charge/discharge switching point becomes shortened. The operation frequency tends to become low. Therefore, in the third embodiment, when the operation frequency per unit time, calculated by operation-frequency calculation section 301, becomes low, a range of the predetermined data-detection condition is widened such that a data-extraction condition for data used as operation objects becomes looser. As a result, it is possible to increase the operation frequency, while somewhat lowering the operation accuracy.

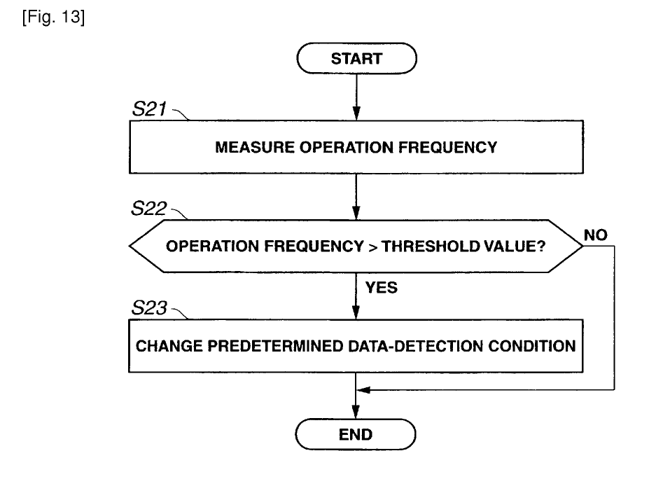

The control routine of the arithmetic processing apparatus of the third embodiment is hereunder described in reference to FIG. 13. FIG. 13 is the flowchart illustrating the control routine executed within the arithmetic processing apparatus of the third embodiment.

At step S21, operation-frequency calculation section 301 detects or measures an operation frequency for calculations of internal resistance or open-circuit voltage, in a unit time. At step S22, controller 100 compares the calculated operation frequency with an operation-frequency threshold value. The operation-frequency threshold value is a preset value. The operation-frequency threshold value is a specified threshold value required to change (narrow or widen) the previously-described predetermined data-detection condition. When the answer to step S22 is in the negative, that is, the calculated operation frequency is lower than the operation-frequency threshold value, one execution cycle of the routine terminates without changing the predetermined condition shown in steps S5 to S8 in FIG. 6. Conversely when the answer to step S22 is in the affirmative, that is, the calculated operation frequency is higher than the operation-frequency threshold value, the routine proceeds to step S23.

### [Math.7]

At step S23, controller 100 changes the predetermined condition shown in steps S5 to S8 in FIG. 6, so as to narrow a range of the predetermined data-detection condition. More concretely, when changing the condition of step S5, charge-current upper limit (Ichg_max) is decreased, and/or charge-current lower limit (Ichg_min) is increased. When changing the condition of step S6, discharge-current upper limit (Idchg_max) is decreased, and/or discharge-current lower limit (Idchg_min) is increased. When changing the condition of step S7, electric-current finite-difference threshold value ΔIc is decreased. When changing the condition of step S8, voltage finite-difference threshold value ΔVc is decreased. In this manner, the predetermined data-detection condition becomes more severe, and then one execution cycle of the control routine of FIG. 13 terminates. By the way, in the third embodiment, after the predetermined condition shown in steps S5 to S8 has been changed by virtue of the data-detection-condition change of step S23, the control routine shown in FIG. 6 is executed.

As discussed above, according to the third embodiment, the operation frequency of arithmetic processing section 102 is calculated by means of operation-frequency calculation section 301. When the calculated operation frequency is higher than the operation-frequency threshold value, the data-extraction condition becomes more severe by narrowing a range of the predetermined data-detection condition, and thus it is possible to enhance the operation accuracy at one execution cycle of arithmetic processing.

### [Math.8]

By the way, according to the control routine of FIG. 13, when the operation frequency is lower than the operation-frequency threshold value, one execution cycle of the routine terminates without changing the predetermined condition for data-detection. In lieu thereof, the controller may be configured to widen a range of the predetermined data-detection condition when the operation frequency is lower than the operation-frequency threshold value. That is, when the result of decision of step S22 is that the operation frequency is lower than the operation-frequency threshold value, controller 100 may serve to change the predetermined data-detection condition shown in steps S5 to S8 in FIG. 6, in a manner so as to widen a range of the predetermined condition. More concretely, when changing the condition of step S5, charge-current upper limit (Ichg_max) is increased, and/or charge-current lower limit (Ichg_min) is decreased. When changing the condition of step S6, discharge-current upper limit (Idchg_max) is increased, and/or discharge-current lower limit (Idchg_min) is decreased. When changing the condition of step S7, electric-current finite-difference threshold value ΔIc is increased. When changing the condition of step S8, voltage finite-difference threshold value ΔVc is increased. In this manner, the predetermined data-detection condition becomes looser, and then one execution cycle of the control routine of FIG. 13 terminates. As can be appreciated from the above, it is preferable to execute appropriately narrowing (see step S23 of FIG. 13) and/or widening of a range of the predetermined data-detection condition, on the basis of the result of comparison between the operation frequency and the operation-frequency threshold value.

As discussed previously, according to the modified routine, when the operation frequency, calculated by operation-frequency calculation section 301, is lower than the operation-frequency threshold value, the data-extraction condition becomes looser by widening a range of the predetermined data-detection condition. As a result, it is possible to properly increase the operation frequency, while somewhat lowering the operation accuracy. However, by taking the moving average or the weighted average of a plurality of calculation results, as a whole it is possible to enhance the operation accuracy of internal resistance and/or open-circuit voltage.

Operation-frequency calculation section 301 of the third embodiment serves as operation-frequency calculation means.

### Fourth Embodiment

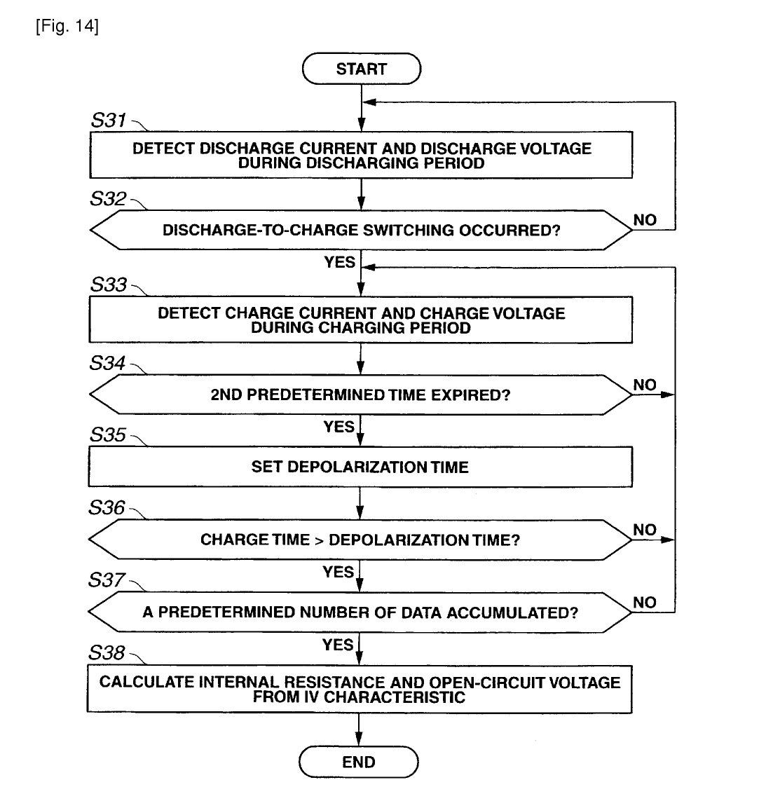

The arithmetic processing apparatus of the fourth embodiment is similar to that of the first embodiment except that the control contents of the fourth embodiment partly differ from the first embodiment. Thus, almost all of elements in the first embodiment (almost all effects provided by the first embodiment) will be applied to the corresponding elements of the fourth embodiment. FIG. 14 is the flowchart illustrating the operation procedure (the control routine) executed within the arithmetic processing apparatus of the fourth embodiment.

In the fourth embodiment, detected data, used as operation objects, are specified based on charge time and/or discharge time, and then an internal resistance and/or an open-circuit voltage of battery 12 is calculated based on the specified data. In a situation where switching between discharge and charge in battery 12 occurs, a polarization may occur in battery 12. For instance, in a use situation where battery 12 is discharged for a long time, and then charged for a short time, and thereafter discharged again, that is, when the discharge time is longer than the charge time, ions tend to become heterogeneous in battery cells of battery 12 due to a long-time discharge, and thus a polarization tends to occur. Thereafter, even if a charging action is carried out for a short time, an adequate depolarization cannot be attained, and thus charging-period detected voltage and current tend to become the detected values of battery cells remaining polarized. When calculating the internal resistance and the open-circuit voltage based on the detected voltage and current values under the polarized state, the operation accuracy tends to deteriorate.

For the reasons discussed above, in the arithmetic processing apparatus of the fourth embodiment, the internal resistance and the open-circuit voltage are calculated by the use of data detected after a depolarization time has expired from the charge/discharge switching point. The control routine and control contents of the fourth embodiment are hereunder described in detail in reference to FIG. 11. FIG. 11 is the flowchart illustrating the control routine executed within the arithmetic processing apparatus of the fourth embodiment.

At step S31, controller 100 detects, based on input information from current sensor 103 and voltage sensor 104, discharge current and discharge voltage of battery 12 during the discharging period at predetermined sampling time intervals.

At step S32, controller 100 determines whether switching from discharge to charge has been performed by charge-discharge switching section 101. When discharge-to-charge switching has not occurred, the routine returns back to step S31, so as to detect again discharge current and discharge voltage. In contrast, when discharge-to-charge switching has occurred, the routine proceeds to step S33.

At step S33, controller 100 detects, based on input information from current sensor 103 and voltage sensor 104, charge current and charge voltage of battery 12 during the charging period at predetermined sampling time intervals.

Next, at step S34, a check is made to determine whether the second predetermined time has expired from the discharge-to-charge switching point. When the second pre-determined time has not expired, it is determined that the data, detected through step S33, are greatly fluctuating and unsuitable for operation objects. Thus, the routine returns to step S33, so as to detect again voltage and current of battery 12. In contrast, when the second predetermined time has expired, the routine proceeds to step S35.

At step S35, a depolarization time is set. The depolarization time is a time required to eliminate a polarization caused by battery discharge before switching to charge. The depolarization time is set or determined depending on the discharge time duration, for the reasons discussed below. The rate of occurrence of polarization is affected by the discharge time. The longer the discharge time, the greater the rate of occurrence of polarization. Hence, controller 100 is configured to set the depolarization time (exactly, the charging-period depolarization time) depending on the discharge time duration before discharge-to-charge switching at step S32. By the way, in setting the discharging-period depolarization time after switching from charge to discharge has occurred, controller 100 is configured to set the discharging-period depolarization time depending on the charge time duration before charge-to-discharge switching has occurred. The depolarization time is preset depending on characteristics of battery 12.

At step S36, controller 100 compares the charge time with the depolarization time. The charge time is a time duration from the discharge-to-charge switching point of step S32 to the point of time for data-detection of step S33. When the charge time is shorter than the depolarization time, it is determined that the data, detected through step S33, are data detected in the battery-cell polarized state and unsuitable for operation objects. Thus, the routine returns to step S33, so as to detect again charge voltage and charge current. In contrast, when the charge time is longer than the depolarization time, it is determined that the data, detected through step S33, are voltage and current data of battery 12 detected in the battery-cell depolarized state and suitable for operation objects. Thus, the routine proceeds to step S37.

At step S37, controller 100 determines whether detected data, used as operation objects for calculating an internal resistance and an open-circuit voltage, have been ac-cumulated to a predetermined number. When the answer to step S37 is in the affirmative, that is, the predetermined number of suitable data have been accumulated in controller 100, the routine proceeds to step S38. Conversely when the answer to step S37 is in the negative, that is, the predetermined number of suitable data have not yet been accumulated in controller 100, the routine returns to step S33.

At step S38, the IV characteristic is derived based on the detected voltage and the detected current included in the detected data, and then an internal resistance and an open-circuit voltage of battery 12 are calculated.

As discussed above, the arithmetic processing apparatus of the fourth embodiment is configured to calculate an internal resistance and an open-circuit voltage of battery 12 by the use of data detected after the depolarization time has expired. By this, the detected voltage and the detected current of battery 12, which is in the polarized state, are not included in the data used as operation objects. Thus, it is possible accurately to derive the IV characteristic, and as a result it is possible to enhance the operation accuracy.

In the fourth embodiment, the charging-period depolarization time after discharge-to-charge switching is determined or set depending on the discharge time duration before the discharge-to-charge switching. On the other hand, the discharging-period depolarization time after charge-to-discharge switching is determined or set depending on the charge time duration before the charge-to-discharge switching. By this, it is possible to set an appropriate depolarization time depending on a rate of occurrence of polarization in battery 12 before switching between charge and discharge occurs, thus enhancing the operation accuracy of internal resistance and/or open-circuit voltage.

In the fourth embodiment, the control routine shown in FIG. 14 is explained and exemplified in the presence of discharge-to-charge switching. As a matter of course, the inventive concept can be applied to the presence of charge-to-discharge switching, but in such a case, regarding technical terms used in each of steps S31-S33 and S36 the two terms “charge” and “discharge” are replaced with each other, and the second pre-determined time recited in step S34 is replaced with the first predetermined time, and setting of charging-period depolarization time executed at step S35 is replaced with setting of discharging-period depolarization time and additionally this discharging-period depolarization time is set depending on the charge time duration before charge-to-discharge switching has occurred.

In the fourth embodiment, suitable data, detected after the depolarization time has expired, are specified by comparing the charging-period depolarization time with the discharge time before discharge-to-charge switching or by comparing the discharging-period depolarization time with the charge time before charge-to-discharge switching. Instead of using the discharge/charge time, an integrated value of battery capacity, an integrated current value, or a current square product (often abbreviated to “ht”) may be used. The integrated value of battery capacity, the integrated current value, or the current square product are parameters, which vary with discharge/charge time elapsed from the charge/discharge switching point. Therefore, on the one hand, the charge/discharge time can be measured indirectly by detecting at least one of these parameters. On the other hand, the depolarization time can be set as a depolarization threshold value determined based on at least one of the integrated value of battery capacity, the integrated current value, or the current square product.

### Fifth Embodiment

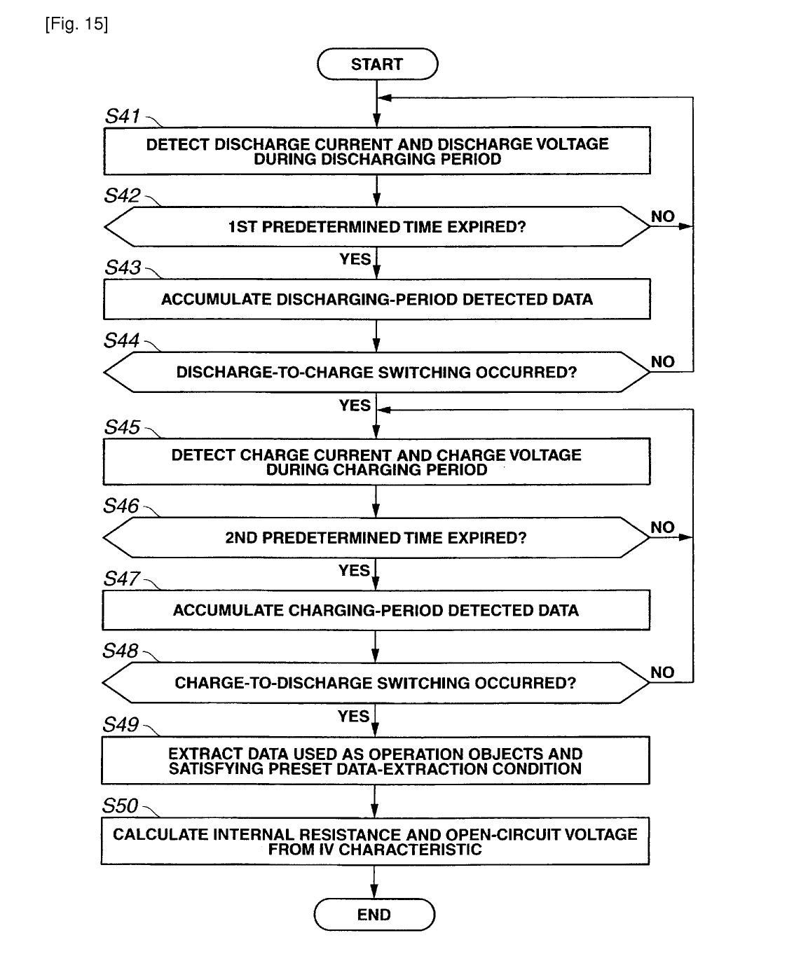

The arithmetic processing apparatus of the fifth embodiment is similar to that of the first embodiment except that the control contents of the fifth embodiment partly differ from the first embodiment. Thus, almost all of elements in the first embodiment (almost all effects provided by the first embodiment) will be applied to the corresponding elements of the fifth embodiment. FIG. 15 is the flowchart illustrating the operation procedure (the control routine) executed within the arithmetic processing apparatus of the fifth embodiment.

In the fifth embodiment, the IV characteristic is derived by the use of both of charging-period detected data and discharging-period detected data, for calculating an internal resistance and/or an open-circuit voltage of battery 12. In calculating the internal resistance and/or the open-circuit voltage, controller 100 is configured to extract detected data as operation objects, in such a manner as to satisfy a condition that a time duration from a charge-to-discharge switching point to a point of time of discharging-period data-detection and a time duration from a discharge-to-charge switching point to a point of time of charging-period data-detection become equal to each other. The data-extraction condition is hereinafter referred to as a “first data-extraction condition”.

For instance, controller 100 is configured to synchronize the timing of charge/discharge switching with the sampling time interval in a manner so as to start a sampling process for informational data to be detected by current sensor 103 and voltage sensor 104 from the timing of charge/discharge switching. Suppose that the sampling time interval is 100 milliseconds, and a time duration from a charge-to-discharge switching point to a point of time when voltage and current of battery 12 becomes stable is 150 milliseconds, and a time duration from a discharge-to-charge switching point to a point of time when voltage and/or current of battery 12 becomes stable is 270 milliseconds. In such a case, discharging-period data-detection timing for stable voltage and current data, which timing satisfies two necessary conditions, namely, 150 milliseconds or more and a multiple of the sampling time interval (100 milliseconds), is 200 milliseconds, 300 milliseconds, 400 milliseconds, and thereafter becomes increased at intervals of 100 milliseconds. On the other hand, charging-period data-detection timing for stable voltage and current data, which timing satisfies two necessary conditions, namely, 270 milliseconds or more and a multiple of the sampling time interval (100 milliseconds), is 300 milliseconds, 400 milliseconds, and thereafter becomes increased at intervals of 100 milliseconds.

For instance, discharging-period data-detection timing, satisfying the previously-discussed first data-extraction condition, becomes 300 milliseconds and 400 milliseconds, whereas charging-period data-detection timing, satisfying the previously-discussed first data-extraction condition, also becomes 300 milliseconds and 400 milliseconds. As appreciated from the above, data detected at the discharging-period data-detection timing of 200 milliseconds corresponds to stable voltage and current data, but this data does not satisfy the first data-extraction condition. Thus, controller 100 excludes this data (detected at the timing of 200 milliseconds) from operation object.

Instead of using the first data-extraction condition, a somewhat different data-extraction condition may be used. For instance, controller 100 may be configured to extract detected data as operation objects, in such a manner as to satisfy a condition that the time difference between a time duration from a charge-to-discharge switching point to a point of time of discharging-period data-detection and a time duration from a discharge-to-charge switching point to a point of time of charging-period data-detection becomes within a predetermined range. The data-extraction condition is hereinafter referred to as a “second data-extraction condition”. The predetermined range means a permissible deviation (or a permissible tolerance) between charging-period data-detection timing and discharging-period data-detection timing. The predetermined range is a preset time-difference range.

For instance, controller 100 is configured to operate current sensor 103 and voltage sensor 104 at predetermined sampling time intervals, such as 100 milliseconds. Suppose that a time duration from a charge-to-discharge switching point to a point of time when voltage and current of battery 12 becomes stable is 150 milliseconds, and a time duration from a discharge-to-charge switching point to a point of time when voltage and current of battery 12 becomes stable is 270 milliseconds. Additionally, suppose that the predetermined range is set to 15 milliseconds.

Assume that, in the presence of charge-to-discharge switching, a sampling process for informational data to be detected by current sensor 103 and voltage sensor 104 has been performed 20 milliseconds later from the charge-to-discharge switching point. In such a case, the timing of discharging-period voltage/current data-detection from the charge-to-discharge switching point, which data-detection is successively performed by means of current sensor 103 and voltage sensor 104, is 20 milliseconds later, 120 milliseconds later, 220 milliseconds later, 320 milliseconds later, and the like. Successive discharging-period data-detection timing for stable voltage and current data from the charge-to-discharge switching point, which timing satisfies a necessary condition, namely, 150 milliseconds or more, is 220 milliseconds later, 320 milliseconds later, and the like.

In addition to the above, assume that, in the presence of discharge-to-charge switching, a sampling process for informational data to be detected by current sensor 103 and voltage sensor 104 has been performed 30 milliseconds later from the discharge-to-charge switching point. In such a case, the timing of charging-period voltage/current data-detection from the discharge-to-charge switching point, which data-detection is successively performed by means of current sensor 103 and voltage sensor 104, is 30 milliseconds later, 130 milliseconds later, 230 milliseconds later, 330 milliseconds later, and so on. Successive charging-period data-detection timing for stable voltage and current data from the discharge-to-charge switching point, which timing satisfies a necessary condition, namely, 270 milliseconds or more, is 330 milliseconds later, 430 milliseconds later, and so on.

The data-detection time difference between the discharging-period detected data (sampled 220 milliseconds later) and the charging-period detected data (sampled 330 milliseconds later) becomes 110 milliseconds, which time difference falls outside of the predetermined range (i.e., the permissible deviation of 15 milliseconds). Thus, the discharging-period detected data (sampled 220 milliseconds later) is excluded from operation object. On the other hand, the data-detection time difference between the discharging-period detected data (sampled 320 milliseconds later) and the charging-period detected data (sampled 330 milliseconds later) becomes 10 milliseconds, which time difference is within the predetermined range (i.e., the permissible deviation of 15 milliseconds). Thus, the discharging-period detected data (sampled 320 milliseconds later) and the charging-period detected data (sampled 330 milliseconds later) are used as operation objects.

That is, in calculating internal resistance and/or open-circuit voltage of battery 12, controller 100 is configured to suitably extract data, using either the first data-ex-traction condition or the second data-extraction condition, and also to calculate internal resistance and/or open-circuit voltage, based on the suitably extracted data, satisfying either the first data-extraction condition or the second data-extraction condition. By this, in the fifth embodiment, in calculating internal resistance and/or open-circuit voltage by the use of both charging-period detected data and discharging-period detected data, the arithmetic processing apparatus is configured to calculate internal resistance and/or open-circuit voltage, while excluding data that the charging-period data-detection timing after the discharge-to-charge switching point greatly deviates from the discharging-period data-detection timing after the charge-to-discharge switching point. As a result, in deriving the IV characteristic, it is possible to enhance the operation accuracy, thus suppressing arithmetic errors for an internal resistance and/or an open-circuit voltage of the battery.

The operation procedure of internal resistance and open-circuit voltage of battery 12, executed within the arithmetic processing apparatus of the fifth embodiment, is hereunder explained in reference to FIG. 15. FIG. 15 shows the operation procedure of internal resistance R and open-circuit voltage Vo when discharge-to-charge switching occurs from a point of time when charge-to-discharge switching has occurred, and then charge-to-discharge switching takes place again.

At step S41, controller 100 detects, based on input information from current sensor 103 and voltage sensor 104, discharge current and discharge voltage of battery 12 during the discharging period.

At step S42, a check is made to determine whether the first predetermined time has expired from the charge-to-discharge switching point. When the first predetermined time has not expired, the routine returns to step S41, so as to detect again voltage and current of battery 12. In contrast, when the first predetermined time has expired, the routine proceeds to step S43.

At step S43, controller 100 accumulates discharging-period data, detected after the first predetermined time has expired.

At step S44, a check is made to determine whether discharge-to-charge switching has occurred. When discharge-to-charge switching has not occurred, the routine returns back to step S41, so as to detect discharge current and discharge voltage at predetermined sampling time intervals. In contrast, when discharge-to-charge switching has occurred, the routine proceeds to step S45.

At step S45, controller 100 detects, based on input information from current sensor 103 and voltage sensor 104, charge current and charge voltage of battery 12 during the charging period.

At step S46, a check is made to determine whether the second predetermined time has expired from the discharge-to-charge switching point. When the second predetermined time has not expired, the routine returns to step S45, so as to detect again voltage and current of battery 12. In contrast, when the second predetermined time has expired, the routine proceeds to step S47.

At step S47, controller 100 accumulates charging-period data, detected after the second predetermined time has expired.

At step S48, a check is made to determine whether charge-to-discharge switching has occurred. When charge-to-discharge switching has not occurred, the routine returns back to step S45, so as to detect charge current and charge voltage at predetermined sampling time intervals. In contrast, when charge-to-discharge switching has occurred, the routine proceeds to step S49.

At step S49, controller 100 extracts data, satisfying the preset data-extraction condition, from the discharging-period detected data accumulated through step S43 and the charging-period detected data accumulated through step S47, while using the preset data-extraction condition (either the first data-extraction condition or the second data-extraction condition). By the way, regarding which of the first data-extraction condition and the second data-extraction condition should be used, either one of the first data-extraction condition and the second data-extraction condition is preset as a given data-extraction condition prior to arithmetic operation.

At step S50, controller 100 derives the IV characteristic by the use of the data extracted through step S49, and then an internal resistance and an open-circuit voltage of battery 12 are calculated.

As discussed above, in the case of the use of the first data-extraction condition, the arithmetic processing apparatus of the fifth embodiment is configured to calculate an internal resistance and an open-circuit voltage of battery 12 by the use of detected data that a time duration from a charge-to-discharge switching point to a point of time of discharging-period data-detection and a time duration from a discharge-to-charge switching point to a point of time of charging-period data-detection become equal to each other. By this, in deriving the IV characteristic, it is possible to enhance the operation accuracy, thus suppressing arithmetic errors for an internal resistance and/or an open-circuit voltage of the battery.

Also, in the case of the use of the second data-extraction condition, the arithmetic processing apparatus of the fifth embodiment is configured to calculate an internal resistance and an open-circuit voltage of battery 12 by the use of detected data that the time difference between a time duration from a charge-to-discharge switching point to a point of time of discharging-period data-detection and a time duration from a discharge-to-charge switching point to a point of time of charging-period data-detection becomes within a predetermined range (i.e., a permissible deviation). By this, in deriving the IV characteristic, it is possible to enhance the operation accuracy, thus suppressing arithmetic errors for an internal resistance and/or an open-circuit voltage of the battery. By the way, in calculating an internal resistance and/or an open-circuit voltage of a secondary battery by the use of a plurality of charging-period detected data and a plurality of discharging-period detected data, controller 100 may be configured to extract the detected data pairs that satisfy the preset data-extraction condition (either the first data-extraction condition or the second data-extraction condition), while checking for the preset data-extraction condition each and every data pair.

1-21. (canceled)

22. An arithmetic processing apparatus comprising:
a charge-discharge switching device for switching between a charge and a discharge of a secondary battery;
a voltage sensor for detecting a voltage of the secondary battery;
a current sensor for detecting an electric current of the secondary battery;
a processor for calculating an internal resistance or an open-circuit voltage of the secondary battery based on data including the voltage detected by the voltage sensor and the current detected by the current sensor; and
the processor configured to derive an IV characteristic by using at least one of charging-period voltage and current data and discharging-period voltage and current data detected after a predetermined time has expired from a charge/discharge switching point at which charge/discharge switching is performed by the charge-discharge switching device, without using the voltage and current data of the secondary battery detected during a time duration from the charge/discharge switching point to the predetermined time, and configured to calculate the internal resistance or the open-circuit voltage from the derived IV characteristic, the predetermined time being set based on a temperature or a deterioration rate of the secondary battery.

23. The arithmetic processing apparatus as claimed in claim 22, wherein:
the predetermined time is a time duration from the charge/discharge switching point to a point of time when a change in each of the voltage and the current of the secondary battery becomes stable.

24. The arithmetic processing apparatus as claimed in claim 22, wherein:
the secondary battery is connected to a battery load, which is activated by the secondary battery serving as an electric power source;
the charge-discharge switching device is configured to perform charge/discharge switching under a power-supply enabling state where an electric power supply from the secondary battery to the battery load is enabled; and
the processor is configured to calculate the internal resistance or the open-circuit voltage by using the data detected outside of the time duration from the charge/discharge switching point to the predetermined time.

25. The arithmetic processing apparatus as claimed in claim 22, wherein:
the processor is configured to calculate the internal resistance or the open-circuit voltage, by using a plurality of charging-period voltage and current data or a plurality of discharging-period voltage and current data, included in the data detected after the predetermined time has expired from the charge/discharge switching point.

26. The arithmetic processing apparatus as claimed in claim 22, wherein:
the processor is configured to calculate the internal resistance or the open-circuit voltage, by using both the charging-period data and the discharging-period data, included in the data detected after the predetermined time has expired from the charge/discharge switching point.

27. The arithmetic processing apparatus as claimed in claim 22, wherein:
the processor is configured to calculate the internal resistance or the open-circuit voltage, by using both the discharging-period data detected after a first predetermined time has expired from a charge-to-discharge switching point and the charging-period data detected after a second predetermined time has expired from a discharge-to-charge switching point, a time length of the first predetermined time and a time length of the second predetermined time being set to be identical to each other.

28. The arithmetic processing apparatus as claimed in claim 22, wherein:
the charge/discharge switching point is a charge-to-discharge switching point;
the processor is configured to calculate the internal resistance or the open-circuit voltage, by using both the charging-period data and the discharging-period data;
the detected current included in the charging-period data is decreasing with time; and
the detected current included in the discharging-period data is increasing with time.

29. The arithmetic processing apparatus as claimed in claim 22, wherein:
the processor is configured to calculate the internal resistance or the open-circuit voltage, by using both the discharging-period data detected after a first predetermined time has expired from a charge-to-discharge switching point and the charging-period data detected after a second predetermined time has expired from a discharge-to-charge switching point; and
a time duration from the charge-to-discharge switching point to a point of time of data-detection of the discharging-period data and a time duration from the discharge-to-charge switching point to a point of time of data-detection of the charging-period data are equal to each other.

30. The arithmetic processing apparatus as claimed in claim 22, wherein:
the processor is configured to calculate the internal resistance or the open-circuit voltage, by using both the discharging-period data detected after a first predetermined time has expired from a charge-to-discharge switching point and the charging-period data detected after a second predetermined time has expired from a discharge-to-charge switching point; and
a time difference between a time duration from the charge-to-discharge switching point to a point of time of data-detection of the discharging-period data and a time duration from the discharge-to-charge switching point to a point of time of data-detection of the charging-period data is within a predetermined range.

31. The arithmetic processing apparatus as claimed in claim 22, wherein:
the processor is configured to calculate the internal resistance or the open-circuit voltage, by using specific data extracted from the detected data and satisfying a predetermined condition.

32. The arithmetic processing apparatus as claimed in claim 31, which further comprises:
the temperature sensor for detecting a temperature of the secondary battery,
wherein the processor is configured to vary the predetermined condition depending on the battery temperature detected by the temperature sensor.

33. The arithmetic processing apparatus as claimed in claim 31, which further comprises:
the deterioration-rate operation part for calculating the deterioration rate of the secondary battery,
wherein the processor is configured to vary the predetermined condition depending on the deterioration rate calculated by the deterioration-rate operation part.

34. The arithmetic processing apparatus as claimed in claim 31, which further comprises:
an operation-frequency counter for measuring an operation frequency for calculations of the internal resistance or the open-circuit voltage;
wherein the processor is configured to narrow a range of the predetermined condition, when the operation frequency is higher than a preset operation-frequency threshold value.

35. The arithmetic processing apparatus as claimed in claim 31, which further comprises:
an operation-frequency counter for measuring an operation frequency for calculations of the internal resistance or the open-circuit voltage;
wherein the processor is configured to widen a range of the predetermined condition, when the operation frequency is lower than a preset operation-frequency threshold value.

36. The arithmetic processing apparatus as claimed in claim 22, which further comprises:
a storage memory for pre-storing a lookup table showing a correlation between a state of charge of the secondary battery and either one of the internal resistance and the open-circuit voltage,
wherein the processor is configured to convert the calculated internal resistance or the calculated open-circuit voltage into a standard scale corresponding to a standard battery state of charge.

37. The arithmetic processing apparatus as claimed in claim 22, which further comprises:
the temperature sensor for detecting the temperature of the secondary battery;
a storage memory for pre-storing a lookup table showing a correlation between the temperature of the secondary battery and either one of the internal resistance and the open-circuit voltage,
wherein the processor is configured to convert the calculated internal resistance or the calculated open-circuit voltage into a standard scale corresponding to a standard battery temperature.

38. The arithmetic processing apparatus as claimed in claim 22, wherein:
the processor is configured to calculate the internal resistance or the open-circuit voltage by using the data detected after a depolarization time of the secondary battery has expired from the charge/discharge switching point.

39. The arithmetic processing apparatus as claimed in claim 36, wherein:
the depolarization time is determined depending on a discharge time duration before discharge-to-charge switching or a charge time duration before charge-to-discharge switching.
